(19) United States
(12) Patent Application Publication
(10) Pub. No.: US 2017/0178985 A1
(43) Pub. Date: Jun. 22, 2017

(54) SEMICONDUCTOR DEVICE

(71) Applicant: Renesas Electronics Corporation, Tokyo (JP)

(72) Inventors: Yoshiaki SATO, Tokyo (JP); Yosuke KATSURA, Gunma (JP)

(21) Appl. No.: 15/333,693

(22) Filed: Oct. 25, 2016

(30) Foreign Application Priority Data
Dec. 17, 2015 (JP) 2015-245884

(51) Int. Cl. H01L 23/04; H01L 21/48; H01L 23/498; H01L 23/00; H01L 25/00; H01L 23/10

(52) U.S. Cl. CPC H01L 23/04; H01L 25/00; H01L 23/10; H01L 23/49827; H01L 23/49816; H01L 23/49822; H01L 24/73; H01L 21/4817; H01L 25/105

(57) ABSTRACT

A semiconductor device includes a semiconductor chip and a package structure mounted on a wiring substrate, and a lid for covering the semiconductor chip, which is fixed to the surface of the wiring substrate, without overlapping with the package structure in plan view. The lid includes an upper surface portion overlapping with the semiconductor chip, a flange portion fixed to the surface of the wiring substrate, and a slant portion for jointing the upper surface portion and the flange portion. Then, a distance from the surface of the wiring substrate to the top surface of the upper surface portion is larger than a distance from the surface of the wiring substrate to the top surface of the flange portion.

### CROSS-REFERENCE TO RELATED APPLICATIONS

The disclosure of Japanese Patent Application No. 2015-245884 filed on Dec. 17, 2015 including the specification, drawings and abstract is incorporated herein by reference in its entirety.

### BACKGROUND

The invention relates to a semiconductor device, for example, a technique effectively applied to a semiconductor device including a plurality of semiconductor chips.

Japanese Unexamined Patent Application Publication No. 2007-95860 discloses a semiconductor device having a plurality of semiconductor chips mounted on a substrate and having a heat radiation plate on the top surface of a part of the semiconductor chips.

In a semiconductor device with a plurality of semiconductor parts mounted on a substrate, there is a technique of providing a heat radiating plate in the semiconductor parts in order to effectively release the heat generated from the semiconductor parts to the outside. As a concrete structural example, for example, a heat radiating plate is provided to cover the semiconductor parts mounted on a substrate and the heat radiating plate is coupled to the respective semiconductor parts by adhesive. However, the semiconductor parts mounted on the substrate are not always identical in thickness and their thicknesses are various. In this case, when a heat radiating plate is provided to cover the whole semiconductor parts of various thicknesses and to be coupled to the respective semiconductor parts through adhesive, an interstice between the top surface of the semiconductor parts and the heat radiating plate necessarily gets larger and the volume of the adhesive for coupling a thin semiconductor part and the heat radiating plate gets larger. As the result, the adhesive between the heat radiating plate and the thin semiconductor part gets thicker and according to this, the heat radiation efficiency of the heat generated in the thin semiconductor part is deteriorated. Especially, when the heating amount in the thin semiconductor part is large, a malfunction caused by a rise of the temperature in the thin semiconductor part easily occurs, hence to deteriorate reliability of a semiconductor device. Therefore, for a semiconductor device provided with a heat radiating plate to cover the semiconductor parts of various thicknesses, it is necessary to consider further improvement from a viewpoint of improving the reliability of a semiconductor device.

Other objects and novel features will be apparent from the description of the specification and the attached drawings.

A semiconductor device according to one embodiment includes a heat radiating material for covering a first semiconductor part, which is fixed to the surface of the substrate, without overlapping with a second semiconductor part in plan view. Here, the heat radiating material includes a first portion overlapping with the first semiconductor part in plan view, a second portion fixed to the surface of the substrate, and a joint portion for jointing the first portion and the second portion. A distance from the surface of the substrate to the top surface of the first portion is not less than a distance from the surface of the substrate to the top surface of the second portion.

According to one embodiment, the reliability of a semiconductor device can be improved.

### BRIEF DESCRIPTION OF THE DRAWINGS

FIG. 1 is a view showing a cross sectional structure of a semiconductor device in the related art.

FIG. 2 is a view showing the cross sectional structure of the semiconductor device in the related art.

FIG. 3A is a top plan view showing the structure of a semiconductor device according to one embodiment and FIG. 3B is a cross-sectional view taken along the line A-A in FIG. 3A.

FIG. 4 is an enlarged view showing a part of FIG. 3B in an enlarged way.

FIG. 5 is a cross-sectional view partially showing a cross section of the wiring substrate.

FIG. 6 is a view schematically showing the state in which wiring included in a first wiring layer of the wiring substrate is disconnected due to the adhesive for adhering a lid to the wiring substrate.

FIG. 7A is a view schematically showing an average positional relation among the wiring substrate, the lid, and the wiring, and FIG. 7B is a cross-sectional view schematically showing that an adhesive area for the adhesive to attach the lid is not provided above the wiring.

FIG. 8A is a view schematically showing a flat positional relation among the wiring substrate, the lid, and a wide pattern and FIG. 8B is a cross-sectional view schematically showing that the adhesive area for the adhesive to attach the lid can be provided above the wide pattern.

FIG. 9A is a view schematically showing the flat positional relation among the wiring substrate, the lid, and the wiring and FIG. 9B is a cross-sectional view schematically showing that the adhesive area for the adhesive to attach the lid can be provided in an area not overlapping with the wiring in plan view.

FIG. 10A is a view schematically showing the flat positional relation among the wiring substrate, the lid, and the wiring and FIG. 10B is a cross-sectional view schematically showing that the adhesive area for the adhesive to attach the lid can be provided in an area overlapping with the wiring in plan view.

FIG. 11 is a schematic view showing a layout structural example of the wiring substrate in the embodiment.

FIG. 12 is a schematic view showing a layout structural example of the wiring substrate in the embodiment.

FIG. 13 is a top plan view showing the state with the lid mounted on the wiring substrate shown in FIG. 11.

FIG. 14 is a top plan view showing the structural example of discontinuously forming application areas of the adhesive.

FIGS. 15A and 15B are views for use in describing the manufacturing process of the semiconductor device in the embodiment: FIG. 15A is a top plan view and FIG. 15B is a cross-sectional view taken along the line A-A in FIG. 15A.

FIGS. 16A and 16B are views for use in describing the manufacturing process of the semiconductor device continued from FIGS. 15A and 15B: FIG. 16A is a top plan view and FIG. 16B is a cross-sectional view taken along the line A-A in FIG. 16A.

FIGS. 17A and 17B are views for use in describing the manufacturing process of the semiconductor device continued from FIGS. 16A and 16B: FIG. 17A is a top plan view and FIG. 17B is a cross-sectional view taken along the line A-A in FIG. 17A.

FIGS. 18A and 18B are views for use in describing the manufacturing process of the semiconductor device continued from FIGS. 17A and 17B: FIG. 18A is a top plan view and FIG. 18B is a cross-sectional view taken along the line A-A in FIG. 18A.

FIGS. 19A and 19B are views for use in describing the manufacturing process of the semiconductor device continued from FIGS. 18A and 18B: FIG. 19A is a top plan view and FIG. 19B is a cross-sectional view taken along the line A-A in FIG. 19A.

FIGS. 20A and 20B are views for use in describing the manufacturing process of the semiconductor device continued from FIGS. 19A and 19B: FIG. 20A is a top plan view and FIG. 20B is a cross-sectional view taken along the line A-A in FIG. 20A.

FIGS. 21A and 21B are views for use in describing the manufacturing process of the semiconductor device continued from FIGS. 20A and 20B: FIG. 21A is a top plan view and FIG. 21B is a cross-sectional view taken along the line A-A in FIG. 21A.

FIGS. 22A and 22B are views for use in describing the manufacturing process of the semiconductor device continued from FIGS. 21A and 21B: FIG. 22A is a top plan view and FIG. 22B is a cross-sectional view taken along the line A-A in FIG. 22A.

FIG. 23 is a top plan view showing the plan structure of a semiconductor device according to a modified example 1.

FIG. 24 is a top plan view showing the plan structure of a semiconductor device according to a modified example 2.

FIG. 25 is a top plan view showing the plan structure of a semiconductor device according to a modified example 3.

FIG. 26 is a top plan view showing the plan structure of a semiconductor device according to a modified example 4.

### DETAILED DESCRIPTION

The following embodiments, if the necessity arises for the sake of convenience, will be described divided into a plurality of sections or forms; unless otherwise specified, they are mutually related to each other and one is related to the other in a part or in the whole modified examples as the detailed and supplementary description.

Further, in case of referring to the number of elements (including piece, numeric value, amount, and range), in the following embodiments, the number is not restricted to the specified number but may be more or less than the specified number, unless otherwise specified and unless otherwise restricted to the specified number apparently on the principle.

Further, in the following embodiments, it is needless to say that the components (including steps) are not always compulsory unless otherwise specified and unless considered compulsory on the principle.

Similarly, in the following embodiments, when referring to the shape and the positional relation of the components, they are actually to contain the similar or quasi shape, unless otherwise specified and unless their shapes and positional relation are apparently different on the principle. This is true to the above numeric value and range.

Further, in all the drawings for describing the embodiments, the same reference codes are attached to the same materials and their repeated description will be omitted. For the sake of easy understanding, hatching may be attached to a top plan view.

### Embodiments

### <Investigation for Improvement>

At first, investigation for improvement in the related art newly found by the inventor et al. will be described with reference to the drawings. Here, “the related art” in this specification is a technique having the problems newly found by the inventor et al., and although it is not the related art well-known, it is the technique intended for the precondition of a new technical spirit (unknown technique).

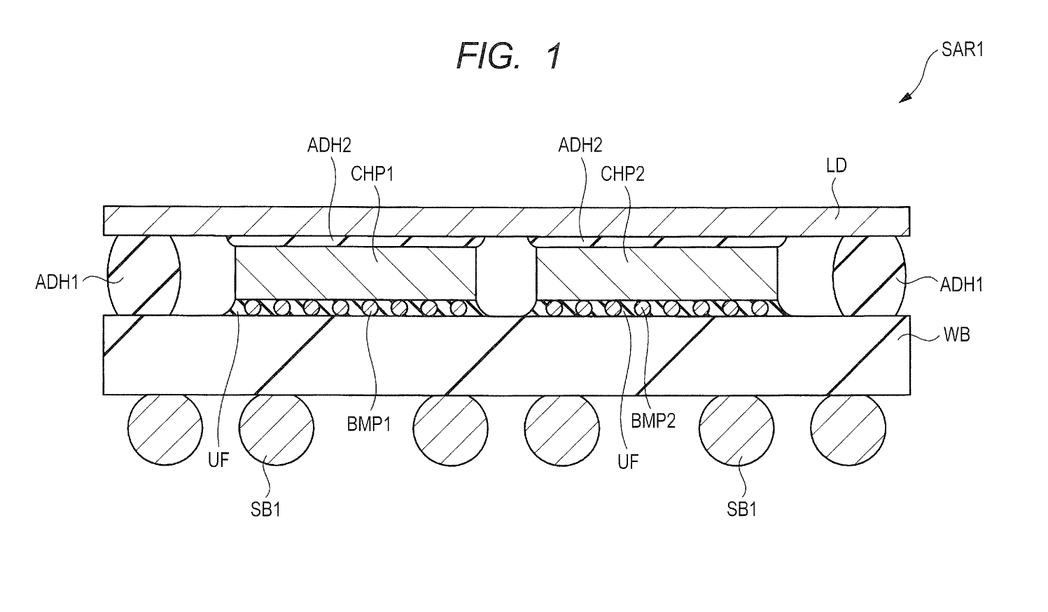

FIG. 1 is a view showing a cross sectional structure of a semiconductor device SAR1 in the related art. In FIG. 1, the semiconductor device SAR1 in the related art includes a wiring substrate WB, and a semiconductor chip CHP1 and a semiconductor chip CHP2 are mounted on the top surface of the wiring substrate WB. On the other hand, a plurality of soldering balls SB1 are mounted on the rear surface of the wiring substrate WB. On the surface of the semiconductor chip CHP1, a plurality of bump electrodes BMP1 are formed and through the bump electrodes BMP1, the semiconductor chip CHP1 is face down mounted on the surface of the wiring substrate WB. Similarly, on the surface of the semiconductor chip CHP2, a plurality of bump electrodes BMP2 are formed and through the bump electrodes BMP2, the semiconductor chip CHP2 is face down mounted on the surface of the wiring substrate WB. Then, underfill UF is filled in the interstice between the semiconductor chip CHP1 and the wiring substrate WB and the interstice between the semiconductor chip CHP2 and the wiring substrate WB.

In the related art, the semiconductor chip CHP1 is, for example, substantially as thick as the semiconductor chip CHP2 and a lid LD working as a heat radiating material is mounted across the rear surface of the semiconductor chip CHP1 and the rear surface of the semiconductor chip CHP2. The lid LD is adhered to the semiconductor chip CHP1 by adhesive ADH2, and similarly, the lid LD is adhered to the semiconductor chip CHP2 by the adhesive ADH2. On the other hand, the lid LD is adhered to the wiring substrate WB through adhesive ADH1.

Here, for example, a microcomputer forming a central processing unit (CPU) is formed on the semiconductor chip CHP1 and a nonvolatile memory is formed on the semiconductor chip CHP2. Here, the central processing unit formed on the semiconductor chip CHP1 controls the nonvolatile memory formed on the semiconductor chip CHP2. Since the central processing unit is formed by a digital circuit including a logic circuit, the semiconductor chip CHP1 is also provided with an oscillator for establishing synchronization. On the other hand, the semiconductor chip CHP2 is also provided with an oscillator in the nonvolatile memory to establish synchronization in order to perform a write operation and delete operation. Especially, the oscillator used for the nonvolatile memory requires a high oscillation accuracy, and therefore, the oscillation accuracy of the oscillator formed on the semiconductor chip CHP2 is higher than the oscillation accuracy of the oscillator formed on the semiconductor chip CHP1.

In the related art formed thus, the inventor et al. have investigated and found that there is still room for improvement, as follows. For example, as shown in FIG. 1, in the related art, the semiconductor chip CHP2 with the nonvolatile memory formed there is mounted on the wiring substrate WB as a bare chip. In this case, for example, due to a difference of the linear expansion coefficient between the wiring substrate WB and the semiconductor chip CHP2, stress easily occurs on the semiconductor chip CHP2. Especially, when the semiconductor chip CHP2 is mounted on the wiring substrate WB as a bare chip, the stress imposed on the semiconductor chip CHP2 gets larger. Especially, a high accuracy oscillator of generating clocks for timing the write operation and the delete operation with the nonvolatile memory is formed on the semiconductor chip CHP2; however, the stress imposed on the semiconductor chip CHP2 deteriorates the oscillation accuracy of the oscillator. When the oscillation accuracy of the oscillator is deteriorated, it is difficult to perform the write operation and the delete operation normally, which may cause an operational failure of the nonvolatile memory. In other words, in the semiconductor chip CHP2 with the nonvolatile memory formed there, the operational failure of the nonvolatile memory easily occurs due to the stress imposed on the semiconductor chip CHP2.

On the other hand, also the semiconductor chip CHP1 with the central processing unit formed there is mounted on the wiring substrate WB as a bare chip and provided with the oscillator. Similarly to the semiconductor chip CHP2, there is a possibility of the stress imposed on the semiconductor chip CHP1 causing a problem; in the semiconductor chip CHP1, however, the operational failure caused by the stress does not become a big problem, compared with the semiconductor chip CHP2. This is because the oscillation accuracy required for the oscillator formed on the semiconductor chip CHP1 is lower than the oscillation accuracy required for the oscillator formed on the semiconductor chip CHP2. In other words, in the semiconductor chip CHP1, the stress imposed on the semiconductor chip CHP1 hardly causes the operational failure of the central processing unit and this operational failure is not such a big problem compared with the operational failure of the nonvolatile memory in the semiconductor chip CHP2. Accordingly, in the semiconductor device SAR1 in the related art shown in FIG. 1, especially the stress imposed on the semiconductor chip CHP2 with the nonvolatile memory formed becomes a problem.

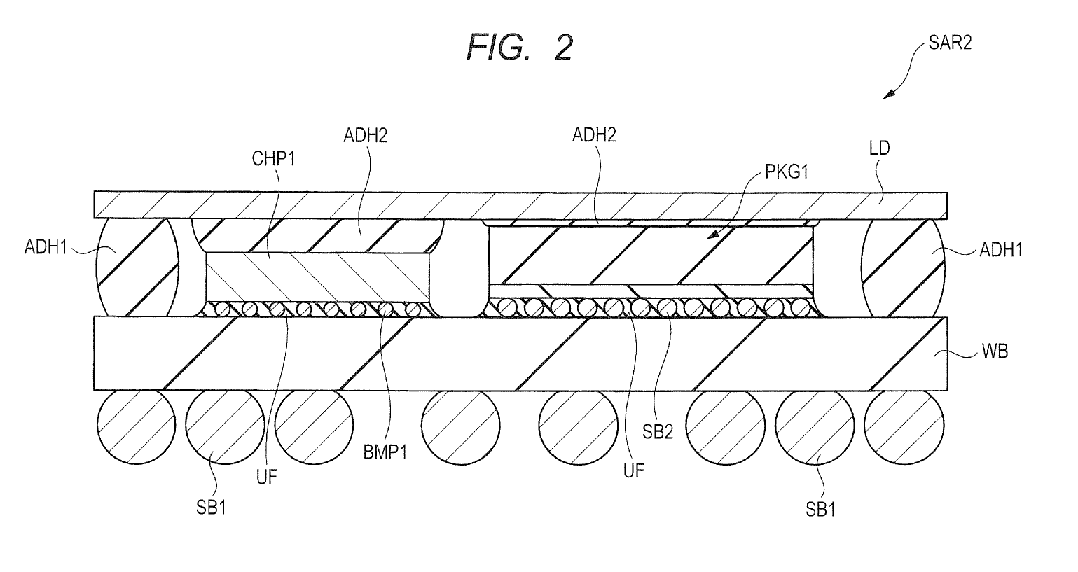

Then, a structure of a semiconductor device SAR2 shown in FIG. 2 is considered. FIG. 2 is a view showing the cross sectional structure of the semiconductor device SAR2 in the related art. The semiconductor device SAR2 shown in FIG. 2 is different from the semiconductor device SAR1 shown in FIG. 1 mainly in that the semiconductor chip CHP2 is not mounted on the wiring substrate WB as a bare chip but that the package structure PKG1 including the semiconductor chip CHP2 as shown in FIG. 2 is mounted on the wiring substrate WB. In the semiconductor device SAR2 shown in FIG. 2, the package structure PKG1 with the semiconductor chip CHP2 sealed is mounted on the wiring substrate WB. Specifically, as shown in FIG. 2, on the rear surface of the package structure PKG1, a plurality of soldering balls SB2 are mounted and through these soldering balls SB2, the package structure PKG1 is mounted on the wiring substrate WB. The underfill UF is filled in the interstice between the package structure PKG1 and the wiring substrate WB. According to thus included semiconductor device SAR2, the semiconductor chip CHP2 is not mounted on the wiring substrate WB as a bare chip but sealed in the package structure PKG1, and the package structure PKG1 is mounted on the wiring substrate WB. As the result, the stress accompanied by the deformation of the wiring substrate WB can be suppressed from being imposed on the semiconductor chip CHP2. In short, the semiconductor chip CHP2 with the nonvolatile memory formed there is sealed within the package structure PKG1, out of direct contact with the wiring substrate WB, and therefore, the semiconductor chip CHP2 is hardly affected by the stress accompanied by the defamation of the wiring substrate WB. According to the semiconductor device SAR2 shown in FIG. 2, the stress imposed on the semiconductor chip CHP2 can be relaxed; as the result, the oscillator formed on the semiconductor chip CHP2 can be kept at a high oscillation accuracy, hence to suppress the operational failure of the nonvolatile memory.

According to this, in the semiconductor device SAR2 shown in FIG. 2, the operational failure of the nonvolatile memory caused by the stress imposed on the semiconductor chip CHP2 can be suppressed; while, in the semiconductor device SAR1 shown in FIG. 1, the inventor et al. have found that there is room for new improvement that was not known, which will be described as follows.

As shown in FIG. 2, in the semiconductor device SAR2, the package structure PKG1 is mounted on the wiring substrate WB, and the semiconductor chip CHP2 is sealed within the package structure PKG1, which necessarily results in making the package structure PKG1 thicker than the semiconductor chip CHP2. Considering that the semiconductor chip CHP1 is substantially as thick as the semiconductor chip CHP2, the package structure PKG1 is thicker than the semiconductor chip CHP1. As the result, as shown in FIG. 2, when the lid LD working as the heat radiating material across the top surface of the semiconductor chip CHP1 and the top surface of the package structure PKG1 is arranged, because the package structure PKG1 is thicker than the semiconductor chip CHP1, the interstice between the top surface of the thin semiconductor chip CHP1 and the lid LD becomes larger. This means that the thickness of the adhesive ADH2 filled in the interstice between the top surface of the semiconductor chip CHP1 and the lid LD becomes larger.

Here, a microcomputer including the central processing unit is formed in the semiconductor chip CHP1 and at the operation time of the central processing unit, heating amount from the semiconductor chip CHP1 increases. Therefore, unless the heat is released efficiently from the semiconductor chip CHP1, the heat is accumulated within the semiconductor chip CHP1 and the temperature of the semiconductor chip CHP1 increases. In this case, there is a fear that malfunction occurs in the circuit formed in the semiconductor chip CHP1 because of the temperature rise. In short, the heating amount of the semiconductor chip CHP1 with the central processing unit formed is larger than that of the semiconductor chip CHP2 with the nonvolatile memory formed. In other words, the semiconductor chip CHP1 with the central processing unit formed has a bigger margin to the stress but a smaller margin to the heating than the semiconductor chip CHP2 with the nonvolatile memory formed. As the result, in the semiconductor device SAR2 shown in FIG. 2, according as the adhesive ADH2 of adhering the top surface of the semiconductor chip CHP1 and the lid LD becomes thicker, the heat radiation efficiency is deteriorated in the semiconductor chip CHP1 having a large heating amount. Because the thermal conductivity of the adhesive ADH2 is not always good, it is preferable that the adhesive ADH2 should be as thin as possible from the viewpoint of the improvement of the heat radiation efficiency and that a distance between the lid LD made of a metal having a high thermal conductivity and the semiconductor chip CHP1 should be as small as possible. Therefore, in the semiconductor device SAR2 shown in FIG. 2, the stress from the wiring substrate WB has a smaller effect on the semiconductor chip CHP2 with the nonvolatile memory formed there having a smaller margin to the stress, while the deterioration of the heat radiation efficiency in the semiconductor chip CHP1 with the central processing unit formed there having a smaller margin to the heating becomes a problem as room for improvement. According to the above, there is desired a structure of a semiconductor device capable of decreasing a bad effect of the stress from the wiring substrate WB on the semiconductor chip CHP2 with the nonvolatile memory formed there having a smaller margin to the stress and improving the heat radiation efficiency in the semiconductor chip CHP1 with the central processing unit formed there having a smaller margin to the heating.

Then, the embodiment proposes a solution to the above problem: a decrease of the stress effect from the wiring substrate WB on the semiconductor chip CHP2 with the nonvolatile memory formed there having a smaller margin to the stress and an improvement of the heat radiation efficiency in the semiconductor chip CHP1 with the central processing unit formed there having a smaller margin to the heating. Hereinafter, the technical spirit in the embodiment with the solution proposed will be described.

### <Structure of Semiconductor Device>

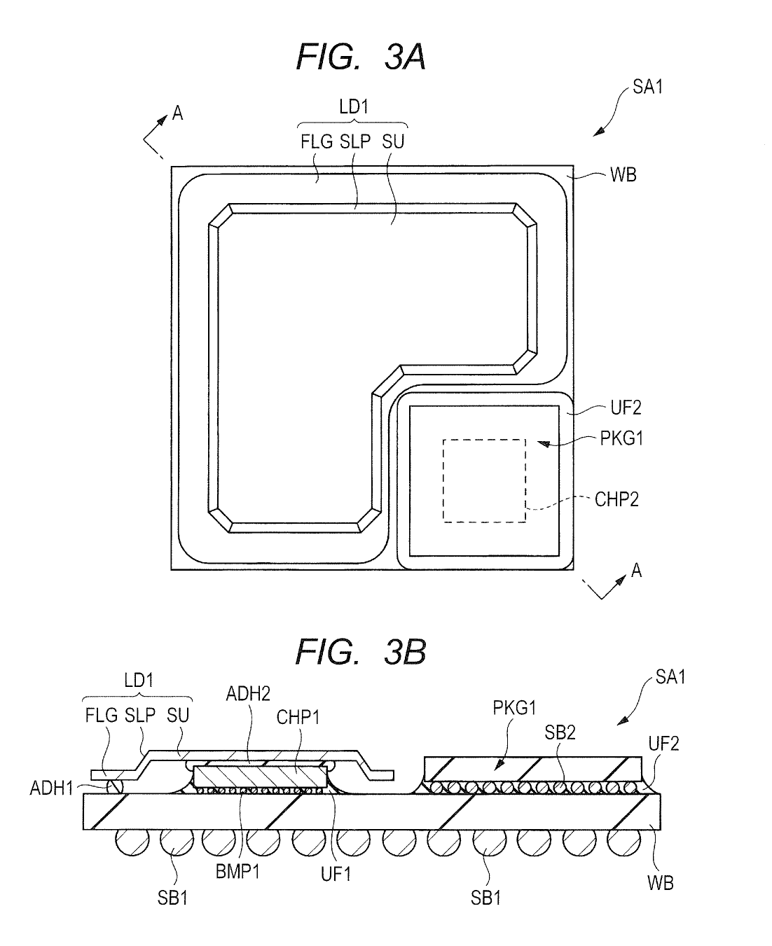

FIGS. 3A and 3B are views showing the structure of a semiconductor device according to the embodiment. Especially, FIG. 3A is a top plan view showing the structure of the semiconductor device according to the embodiment and FIG. 3B is a cross-sectional view taken along the line A-A in FIG. 3A.

At first, in FIG. 3A, the semiconductor device SA1 in the embodiment has a rectangular shaped wiring substrate WB, and on the surface of the wiring substrate WB, the lid LD1 made of a metal working as a heat radiating material and the package structure PKG1 are arranged without overlapping with each other in plan view. For example, the lid LD1 is formed in a shape of L, while the package structure PKG1 is famed in a rectangular shape; and the plane area of the lid LD1 is larger than that of the package structure PKG1. According to this, the heat radiation efficiency of the lid LD1 working as the heat radiating material can be improved.

As shown in FIG. 3A, the lid LD1 includes an upper surface portion SU, a slant portion SLP, and a flange portion FLG. The flange portion FLG is adhered to the surface of the wiring substrate WB and the slant portion SLP works to couple the flange portion FLG and the upper surface portion SU.

On the other hand, as shown in FIG. 3A, for example, the rectangular shaped semiconductor chip CHP2 is sealed within the package structure PKG1. The underfill UF2 is formed to surround the package structure PKG1, hence to improve the joint reliability of the package structure PKG1 and the wiring substrate WB.

Continuously, in FIG. 3B, the semiconductor chip CHP1 is mounted in a first area on the surface of the wiring substrate WB, while the package structure PKG1 is mounted in a second area on the surface of the wiring substrate WB different from the first area. A plurality of bump electrodes BMP1 are formed on the bottom surface of the semiconductor chip CHP1, and the semiconductor chip CHP1 is mounted on the surface of the wiring substrate WB through the plurality of the bump electrodes BMP1 as a bare chip. Then, the underfill UF1 is formed between the semiconductor chip CHP1 and the wiring substrate WB so as to fill the interstices between the respective bump electrodes BMP1. On the other hand, a plurality of soldering balls SB2 are formed on the bottom surface of the package structure PKG1 and the package structure PKG1 is mounted on the surface of the wiring substrate WB through the plurality of the soldering balls SB2. Then, the underfill UF2 is formed between the package structure PKG1 and the wiring substrate WB so as to fill the interstices between the respective soldering balls SB2. Here, on the rear surface of the wiring substrate WB, a plurality of soldering balls SB1 are mounted.

As shown in FIG. 3B, the lid LD1 made of a metal material is arranged to cover the semiconductor chip CHP1 and fixed to the surface of the wiring substrate WB, without overlapping with the package structure PKG1 in plan view. The lid LD1 is fixed to the wiring substrate WB, for example, by the adhesive ADH1. Further, the adhesive ADH2 intervenes between the top surface of the semiconductor chip CHP1 and the lid LD1 and this adhesive ADH2 adheres the lid LD1 to the semiconductor chip CHP1.

As shown in FIG. 3B, the lid LD1 includes the upper surface portion SU overlapping the semiconductor chip CHP1, the flange portion FLG fixed to the surface of the wiring substrate WB, and the slant portion SLP coupling the upper surface portion SU and the flange portion FLG. In the semiconductor device SA1 according to the embodiment, as shown in FIG. 3B, a distance from the surface of the wiring substrate WB to the top surface of the upper surface portion SU of the lid LD1 is larger than the distance from the surface of the wiring substrate WB to the top surface of the flange portion FLG of the lid LD1.

Further, in the semiconductor device SA1 according to the embodiment, for example, as shown in FIG. 3B, the flange portion FLG of the lid LD1 includes an adhesive portion where the adhesive ADH1 intervenes between the surface of the wiring substrate WB and itself and a non-adhesive portion where no adhesive ADH1 intervenes therebetween.

As shown in FIG. 3B, in the semiconductor device SA1 according to the embodiment, the semiconductor chip CHP1 is thinner than the package structure PKG1. In other words, the package structure PKG1 is thicker than the semiconductor chip CHP1. The upper surface portion SU of the lid LD1 is positioned higher than the top surface of the package structure PKG1. In other words, the top surface of the package structure PKG1 is positioned lower than the upper surface portion SU of the lid LD1.

In the semiconductor chip CHP1 shown in FIG. 3B, a microcomputer including the central processing circuit (central processing unit) is formed. In short, the semiconductor chip CHP1 according to the embodiment is System On Chip (SOC). On the other hand, the semiconductor chip CHP2 (refer to FIG. 3A) exists within the package structure PKG1 and in the semiconductor chip CHP2, a nonvolatile memory forming a nonvolatile memory circuit is formed. In the semiconductor device SA1 according to the embodiment, the semiconductor chip CHP1 and the semiconductor chip CHP2 existing within the package structure PKG1 are electrically coupled to each other, so that the central processing unit formed in the semiconductor chip CHP1 controls the nonvolatile memory formed in the semiconductor chip CHP2. Especially, the central processing unit and the nonvolatile memory are digital circuits, requiring clock signals as a reference of operation; therefore, oscillators are provided in both the semiconductor chip CHP1 with the central processing unit formed and the semiconductor chip CHP2 with the nonvolatile memory formed. Especially, for the operation of the nonvolatile memory, a high accuracy clock signal is required; therefore, the oscillator formed in the semiconductor chip CHP2 has a higher oscillation accuracy than the oscillator formed in the semiconductor chip CHP1.

The semiconductor device SA1 according to the embodiment is formed as mentioned above. The outline structure of the semiconductor device SA1 is summarized as follows. The semiconductor device SA1 in the embodiment includes the wiring substrate WB having a surface, the semiconductor chip CHP1 mounted in the first area on the surface of the wiring substrate WB, the package structure PKG1 mounted in the second area on the surface of the wiring substrate WB, and the lid LD1 for covering the semiconductor chip CHP1, which is fixed to the surface of the wiring substrate WB, without overlapping with the package structure PKG1 in plan view. Here, the lid LD1 includes the upper surface portion SU overlapping the semiconductor chip CHP1 in plan view, the flange portion FLG fixed to the surface of the wiring substrate, and the slant portion SLP of coupling the upper surface portion SU and the flange portion FLG.

Here, the semiconductor chip CHP1 and the semiconductor chip CHP2 are semiconductor parts and the lid LD1 is a heat radiating material. According to this, the semiconductor device SA1 includes a substrate (wiring substrate WB) having a surface, a first semiconductor part (semiconductor chip CHP1) mounted in the first area on the surface of the substrate, a second semiconductor part (semiconductor chip CHP2) mounted in the second area on the surface of the substrate, and a heat radiating material (lid LD1) for covering the first semiconductor part, which is fixed to the surface of the substrate, without overlapping with the second semiconductor part in plan view. The heat radiating material includes a first portion (the upper surface portion SU) overlapping the first semiconductor part in plan view, a second portion (flange portion FLG) fixed to the surface of the substrate, and a joint portion (the slant portion SLP) for jointing the first portion and the second portion.

### Characteristics in the Embodiment

Next, characteristics in the embodiment will be described. The first characteristic in the first embodiment is that, for example, as shown in FIGS. 3A and 3B, on the assumption that the semiconductor chip CHP1 and the package structure PKG1 are mounted on the wiring substrate WB, the lid LD1 is provided to cover the semiconductor chip CHP1 and fixed to the surface of the wiring substrate WB without overlapping with the package structure PKG1 in plan view.

According to this, the semiconductor chip CHP2 with the nonvolatile memory formed is not mounted on the wiring substrate WB as a bare chip but mounted on the wiring substrate WB in a state of being sealed within the package structure PKG1. According to the semiconductor device SA1 of the embodiment, it is possible to suppress the stress accompanied by the deformation of the wiring substrate WB from being imposed on the semiconductor chip CHP2. In other words, the semiconductor chip CHP2 with the nonvolatile memory formed is sealed within the package structure PKG1, out of direct contact with the wiring substrate WB; therefore, the semiconductor chip CHP2 is hardly affected by the stress accompanied by the deformation of the wiring substrate WB. Thus, the semiconductor device SA1 in the embodiment shown in FIGS. 3A and 3B can relax the stress imposed on the semiconductor chip CHP2; as the result, it is possible to keep the oscillation accuracy of the oscillator formed in the semiconductor chip CHP2, hence to suppress the operational failure of the nonvolatile memory.

According to the first characteristic in the embodiment, as shown in FIGS. 3A and 3B, the lid LD1 is formed to cover the semiconductor chip CHP1, while it is formed not to overlap with the package structure PKG1 in plan view. As the result, according to the first characteristic in the embodiment, the heat radiation efficiency from the semiconductor chip CHP1 with the central processing unit having a large heating amount formed there can be improved. Therefore, according to the first characteristic in the embodiment, a malfunction of the circuit caused by a temperature rise in the semiconductor chip CHP1 can be suppressed and accordingly, the reliability of the semiconductor device SA1 can be improved. In the embodiment, in order to relax the stress imposed on the semiconductor chip CHP2 having the nonvolatile memory, the semiconductor chip CHP2 is sealed within the package structure and the package structure PKG1 is mounted on the wiring substrate WB. According to this, in the semiconductor device SA1 of the embodiment, the package structure PKG1 is thicker than the semiconductor chip CHP1 having the central processing unit. For example, like the related art shown in FIG. 2, when the lid LD is arranged across the semiconductor chip CHP1 and the package structure PKG1, the interstice between the thin semiconductor chip CHP1 and the lid LD becomes larger and the adhesive ADH2 of a low thermal conductivity to fill the interstice gets thicker. As the result, like the related art shown in FIG. 2, the heat radiation efficiency from the semiconductor chip CHP1 is deteriorated in the structure of arranging the flat plate lid LD across the semiconductor chip CHP1 and the package structure PKG1 having different thicknesses. In this case, the temperature of the semiconductor chip CHP1 rises, hence to raise the possibility of the malfunction occurring in the circuit formed in the semiconductor chip CHP1. Especially, when a large central processing unit of a large heating amount is formed in the semiconductor chip CHP1, it is considered that the malfunction of the circuit easily may occur.

On the contrary, the semiconductor device SA1 according to the embodiment shown in FIGS. 3A and 3B, is provided with the lid LD1 for covering the semiconductor chip CHP1, which is fixed to the surface of the wiring substrate WB, without overlapping with the package structure PKG1 in plan view (first characteristic). According to the embodiment, since the lid LD1 does not have to cover the package structure PKG1, the lid LD1 can be formed to cover only the semiconductor chip CHP1 thereby to reduce the interstice between the semiconductor chip CHP1 and itself, regardless of the thickness of the package structure PKG1. This makes thinner the adhesive ADH2 of a low thermal conductivity to adhere the lid LD1 to the semiconductor chip CHP1. In other words, the semiconductor chip CHP1 can be closer to the lid LD1 formed of a metal material of a high thermal conductivity, hence to release the heat generated in the semiconductor chip CHP1 from the lid LD1 efficiently.

According to the first characteristic in the embodiment, the lid LD1 is arranged to cover only the semiconductor chip CHP1; therefore, the lid LD1 of a high thermal conductivity can be arranged to be closer to the semiconductor chip CHP1, regardless of the thickness of the package structure PKG1, hence to improve the heat radiation efficiency from the semiconductor chip CHP1. According to the semiconductor device SA1 of the embodiment, it is possible to relax the stress imposed on the semiconductor chip CHP2 and simultaneously improve the heat radiation efficiency from the semiconductor chip CHP1. The embodiment can suppress the malfunction of the circuit formed in the semiconductor chip CHP1, while suppressing the operational failure of the nonvolatile memory formed in the semiconductor chip CHP2, thereby obtaining a remarkable effect to improve the reliability of the semiconductor device SA1.

Continuously, the second characteristic in the embodiment is that, for example, as shown in FIG. 3B, the lid LD1 includes the upper surface portion SU, the flange portion FLG, and the slant portion SLP. Specifically, the lid LD1 includes the upper surface portion SU arranged on the semiconductor chip CHP1, the flange portion FLG fixed to the surface of the wiring substrate WB, and the slant portion SLP of coupling the upper surface portion SU and the flange portion FLG. Thus, according to the second characteristic in the embodiment, a distance from the surface of the wiring substrate WB to the top surface of the upper surface portion SU gets larger than the distance from the surface of the wiring substrate WB to the top surface of the flange portion FLG.

As the result, according to the second characteristic in the embodiment, the following effect can be obtained. For example, the lid LD1 is formed by the upper surface portion SU, the flange portion FLG, and the slant portion SLP, which can improve the rigidity of the lid LD1. Specifically, according to the second characteristic in the embodiment, the lid LD1 is not formed in a flat plate shape, but formed in the rigid structure realized by the upper surface portion SU, the flange portion FLG, and the slant portion (taper shape) SLP. As the result, even when a thermal load is imposed on the semiconductor device SA1, a warp of the wiring substrate WB can be suppressed. In short, according to the semiconductor device SA1 in the embodiment, since the rigid lid LD1 is fixed to the wiring substrate WB, even when a warp tries to occur in the wiring substrate WB, the rigid lid LD1 can suppress the above, hence to improve the reliability of the semiconductor device SA1.

According to the second characteristic in the embodiment, as shown in FIG. 3B, since the flange portion FLG of the lid LD1 is close to the wiring substrate WB, an interstice (space) between the flange portion FLG of the lid LD1 and the surface of the wiring substrate WB can be reduced. This makes smaller the application amount of the adhesive ADH1 for adhering the flange portion FLG of the lid LD1 to the surface of the wiring substrate WB.

With respect to this point, for example, in the case of using the flat plate lid LD shown in the related art in FIG. 2, the interstice between the flat plate lid LD and the surface of the wiring substrate WB necessarily gets larger and the application amount of the adhesive ADH1 filling the interstice gets more. An increase in the application amount of the adhesive ADH1 means that the corresponding application area for the adhesive ADH1 has to be secured, resulting in an increasing dead space as the application area for the adhesive ADH1; as the result, the semiconductor device SAR2 is increased in size.

On the contrary, according to the second characteristic in the embodiment, the interstice between the flange portion FLG of the lid LD1 and the surface of the wiring substrate WB can be reduced; therefore, the application amount of the adhesive ADH1 for adhering the flange portion FLG of the lid LD1 to the surface of the wiring substrate WB can be reduced. According to the second characteristic in the embodiment, this makes the application area of the adhesive ADH1 smaller, thereby achieving the downsizing of the semiconductor device SA1.

Further, by reducing the interstice between the flange portion FLG of the lid LD1 and the surface of the wiring substrate WB, the following effect can be obtained. Specifically, the adhesive ADH1 generally has a higher heat resistance compared to the metal material. From the viewpoint of improving the heat radiation efficiency, it is preferable that the adhesive ADH1 filling the interstice between the flange portion FLG of the lid LD1 and the surface of the wiring substrate WB should be thinner. For example, in the case of using the flat plate lid LD shown in the related art in FIG. 2, the interstice between the flat plate lid LD and the surface of the wiring substrate WB necessarily gets larger and the adhesive ADH1 to fill the interstice gets thicker. In the case of using the flat plate lid LD, the heat generated in the semiconductor chip CHP1 is transmitted to the lid LD made of a metal material and released. Here, since the adhesive ADH1 of a high heat resistance which adheres the lid LD to the wiring substrate WB is thick, the heat transmitted to the lid LD is hardly transmitted to the wiring substrate WB. In short, in the flat plate lid LD shown in the related art in FIG. 2, a radiation path to the wiring substrate WB does not work fully as a heat radiation path of the heat transmitted to the lid LD. In other words, in the related art shown in FIG. 2, mainly the heat radiation path from the lid LD is restricted to the heat radiation path through air and from the viewpoint of improving the heat radiation efficiency from the semiconductor device SAR2 to the outside environment, there exists room for improvement.

On the contrary, in the embodiment, the interstice between the flange portion FLG of the lid LD1 and the surface of the wiring substrate WB can be reduced; therefore, the adhesive ADH1 of a high heat resistance to fill the interstice between the flange portion FLG of the lid LD1 and the surface of the wiring substrate WB is reduced in thickness. According to the semiconductor device SA1 in the embodiment, the radiation path to the wiring substrate WB works fully as the heat radiation path of the heat transmitted to the lid LD1. In short, in the embodiment, the heat radiation path starting from the lid LD1 is not restricted to the heat radiation path through air but the radiation path to the wiring substrate WB also contributes to effective release of the heat generated in the semiconductor chip CHP1. According to the second characteristic in the embodiment, the radiation path to the wiring substrate WB can be fully used, hence to improve the heat radiation efficiency from the semiconductor device SA1 to the outside environment.

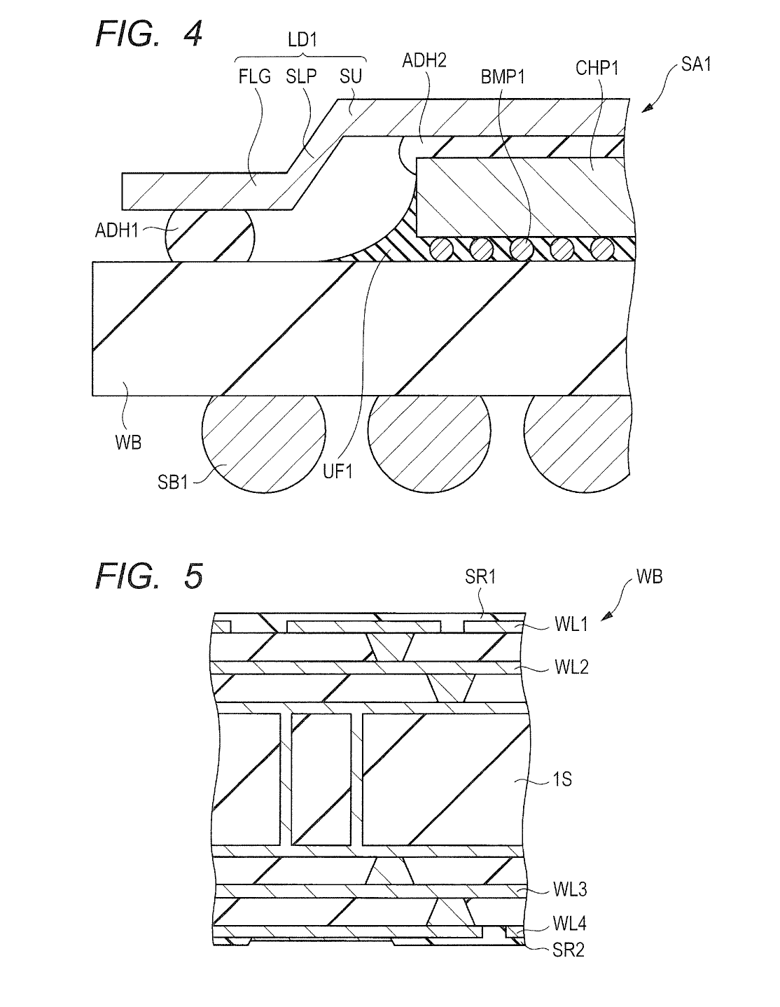

Next, the third characteristic in the embodiment will be described. FIG. 4 is an enlarged view of showing a part of FIG. 3B. For example, the third characteristic in the embodiment, in FIG. 4, is that the adhesive ADH1 for adhering the flange portion FLG of the lid LD1 to the wiring substrate WB and the adhesive ADH2 for adhering the upper surface portion SU of the lid LD1 to the semiconductor chip CHP1 are famed of different materials. For the adhesive ADH1 for adhering the flange portion FLG of the lid LD1 to the wiring substrate WB, a function for assuredly fixing the flange portion FLG to the wiring substrate WB is preferentially required. On the other hand, for the adhesive ADH2 for adhering the upper surface portion SU of the lid LD1 to the semiconductor chip CHP1, a function for improving the heat radiation efficiency from the semiconductor chip CHP1 to the lid LD1 through the adhesive ADH2 is preferentially required. According to the third characteristic in the embodiment such that the adhesive ADH1 and the adhesive ADH2 are made of different materials, as the material of the adhesive ADH1, a material of high material strength is used and as the material of the adhesive ADH2, a material of high thermal conductivity is used. In short, according to the third characteristic in the embodiment, a material can be selected depending on the preferential use advantageously. For example, as the adhesive ADH1 for adhering the flange portion FLG of the lid LD1 to the wiring substrate WB, a thermosetting resin mainly made of epoxy resin can be used and further, a filler containing silicon oxide may be blended in the thermosetting resin in order to reinforce the material strength. On the other hand, the adhesive ADH2 for adhering the upper surface portion SU of the lid LD1 to the semiconductor chip CHP1, a rubber resin mainly made of silicon resin can be used and further, a filler containing metal or metal oxide may be blended there in order to enhance the thermal conductivity. The filler may contain the metal or metal oxide also in the adhesive ADH1, in order to enhance the thermal conductivity. This is because, in the embodiment, the heat radiation path from the flange portion FLG of the lid LD1 to the wiring substrate WB is regarded as an important matter and synergistic effects with the thinned adhesive ADH1 according to the above mentioned second characteristic and the improvement in the thermal conductivity of the adhesive ADH1 itself, the heat radiation efficiency from the flange portion FLG to the wiring substrate WB can be improved. Therefore, as the adhesive ADH1, it is preferable that the filler containing silicon oxide may be blended from the viewpoint of improving the material strength and that the filler containing the metal or metal oxide may be blended from the viewpoint of improving the thermal conductivity.

The fourth characteristic in the embodiment will be described. The fourth characteristic in the embodiment is that, for example, as shown in FIG. 3, the underfill UF1 to fill the interstice between the semiconductor chip CHP1 and the wiring substrate WB and the underfill UF2 to fill the interstice between the package structure PKG1 and the wiring substrate WB are made of different materials. According to this, a mounting reliability can be improved both in the semiconductor chip CHP1 and the package structure PKG1. As the result, a reliability of the whole semiconductor device SA1 in the embodiment can be improved.

For example, the underfill UF1 to fill the interstice between the wiring substrate WB and the semiconductor chip CHP1 has a function of improving the mounting reliability in the semiconductor chip CHP1. Specifically, since the wiring substrate WB and the semiconductor chip CHP1 are formed of different materials, the linear expansion coefficient of the wiring substrate WB is different from the linear expansion coefficient of the semiconductor chip CHP1. Unless some countermeasure is taken, due to a difference between the both linear expansion coefficients, a warp may occur in the wiring substrate WB and the semiconductor chip CHP1 and the bump electrodes BMP1 may fall off, thereby causing a mounting failure. Therefore, the underfill UF1 for exclusive use to fill the interstice between wiring substrate WB and the semiconductor chip CHP1, depending on the difference of the linear expansion coefficient between the wiring substrate WB and the semiconductor chip CHP1, is used, which can suppress the warp and the falling off of the bump electrodes BMP1.

Similarly, the underfill UF2 to fill the interstice between the wiring substrate WB and the package structure PKG1 has a function of improving the mounting reliability of the package structure PKG1. Since the wiring substrate WB and the package structure PKG1 are formed of different materials, the linear expansion coefficient of the wiring substrate WB is different from that of the package structure PKG1. Unless some countermeasure is taken, due to the difference between the both linear expansion coefficients, a warp may occur in the wiring substrate WB and the package structure PKG1 and the soldering balls SB2 may fall off, thereby causing the mounting failure. Therefore, the suitable underfill UF2 for exclusive use to fill the interstice between wiring substrate WB and the package structure PKG1, depending on the difference of the linear expansion coefficient between the wiring substrate WB and the package structure PKG1, is used, which can suppress the warp and the falling off of the soldering balls BMP2.

Here, the material of the semiconductor chip CHP1 is different from that of the package structure PKG1. Accordingly, the material of the underfill UF1 to fill the interstice between the wiring substrate WB and the semiconductor chip CHP1 may be different from that of the underfill UF2 to fill the interstice between the wiring substrate WB and the package structure PKG1.

For example, in the semiconductor device SA1 to be mounted on a vehicle, requiring a high quality, the underfill UF1 and the underfill UF2 can be formed of different materials. Thus, a suitable material for establishing the mounting reliability between the semiconductor chip CHP1 and the wiring substrate WB can be selected as the underfill UF1 to fill the interstice between the wiring substrate WB and the semiconductor chip CHP1. Similarly, a suitable material for establishing the mounting reliability between the package structure PKG1 and the wiring substrate WB wiring substrate WB can be selected as the underfill UF2 to fill the interstice between the wiring substrate WB and the package structure PKG1. According to the fourth characteristic in the embodiment, by using the respective underfills for the exclusive uses, both the mounting reliability of the semiconductor chip CHP1 and the mounting reliability of the package structure PKG1 can be improved at the maximum. As the result, according to the semiconductor device SA1 in the embodiment, a high quality can be secured.

However, when a high quality semiconductor device SA1 with a high mounting reliability can be achieved, the underfill UF1 to fill the interstice between the wiring substrate WB and the semiconductor chip CHP1 and the underfill UF2 to fill the interstice between the wiring substrate WB and the package structure PKG1 can be formed of the same material. For example, in the embodiment, as shown in FIG. 3B, the rigid lid LD1 having the second characteristic fixes the semiconductor chip CHP1 assuredly and the rigid lid LD1 suppresses a warp of the wiring substrate WB itself. According to this, in the embodiment, even when the underfill UF1 and the underfill UF2 are formed of the same material, the semiconductor device SA1 of a high quality can be provided. Therefore, considering this, when the underfill UF1 and the underfill UF2 are formed of the same material, this material should be preferably a material suitable for the mounting reliability of the package structure PKG1 rather than a material suitable for the mounting reliability of the semiconductor chip CHP1. This is because, in the embodiment, the package structure PKG1 is not covered with the lid LD1 and not fixed by the lid LD1 and therefore, it is important to make the underfill UF2 work as a stress relaxing layer (cushion layer) enough to relax the generation of the stress caused by the difference of the linear expansion coefficient.

As mentioned above, in the embodiment, from the viewpoint of providing a high quality semiconductor device SA1, the underfill UF1 and the underfill UF2 can be formed of different materials. In the embodiment, however, the rigid lid LD1 having the second characteristic assuredly fixes the semiconductor chip CHP1; therefore, even when the underfill UF1 and the underfill UF2 are formed of the same material, a high quality semiconductor device SA1 with a high mounting reliability can be provided. In this case, compared with the case of forming the underfill UF1 and the underfill UF2 of different materials, the manufacturing cost can be reduced.

The fifth characteristic in the embodiment will be described. The fifth characteristic in the embodiment is that, for example, as shown in FIG. 3B, the surface of the lid LD1 is positioned higher than the surface of the package structure PKG1. According to this, for example, at carrying time, when the semiconductor device SA1 in the embodiment is in contact with an obstacle, the lid LD1 arranged at a higher position may be often in contact with the obstacle. This can protect the package structure PKG1 not protected by the lid LD1 from contacting the outside obstacle.

Further, together with the fifth characteristic in the embodiment, it is effective that the plan shape of the lid LD1 can be famed in a shape of L, as shown in FIG. 3A, and that the plan size of the lid LD1 can be enlarged to occupy more than a half of the plan size of the wiring substrate WB. This is because, in this case, even when turning the semiconductor device SA1 upside down, the height of the top surface of the lid LD1 can suppress the semiconductor device SA1 from inclining against the surface, hence to secure the flat positioning of the semiconductor device SA1.

According to the above, according to the fifth characteristic in the embodiment, the semiconductor chip CHP2 sealed within the package structure PKG1 can be protected. Further, when turning the semiconductor device SA1 upside down, the semiconductor device SA1 can be secured at a flat position; therefore, the workability in the process of mounting a plurality of soldering balls SB1 on the rear surface of the wiring substrate WB and the workability for a customer to handle can be improved.

### <Investigation of Further Improvement>

The inventor et al. have investigated further improvement, which will be described. Specifically, as shown in FIG. 3B, the lid LD1 is adhered to the wiring substrate WB by the adhesive ADH1; here, the inventor et al. have found room for improvement in the adhesive area, which will be described with reference to the drawings.

FIG. 5 is a cross-sectional view partially showing a cross section of the wiring substrate WB. As shown in FIG. 5, a multilayered wiring layer is formed in the wiring substrate WB. Specifically, a wiring WL2 and a wiring WL1 are formed on the side of the top surface of a core substrate 1S and a solder resist film SR1 is formed to cover the wiring WL1. On the other hand, on the side of the rear surface of the core substrate 1S, a wiring WL3 and a wiring WL4 are formed and a solder resist film SR2 is formed to cover the wiring WL4. Here, for the sake of convenience, the layer including the wiring WL1 formed in the depth nearest to the top surface of the wiring substrate WB is called a first wiring layer and the layer including the wiring WL2 famed in the underlayer of the wiring WL1 is called a second wiring layer. Similarly, the layer including the wiring WL4 formed in the depth nearest to the rear surface of the wiring substrate WB is called a fourth wiring layer and the layer including the wiring WL3 formed at a position nearer to the core substrate 1S than the wiring WL4 is called a third wiring layer. According to this, the wiring substrate WB includes the first wiring layer and the second wiring layer formed on the side of the top surface of the core substrate 1S and the third wiring layer and the fourth wiring layer formed on the side of the rear surface of the core substrate 1S. For example, a through hole with a conductive film (plating film) formed on its inner wall is famed in the core substrate 1S and through this through hole, the wiring layer (first wiring layer and second wiring layer) formed on the side of the top surface of the core substrate 1S is electrically coupled to the wiring layer (the third wiring layer and the fourth wiring layer) formed on the side of the rear surface of the core substrate 1S. As shown in FIG. 5, the first wiring layer including the wiring WL1 is electrically coupled to the second wiring layer including the wiring WL2 by plug. Similarly, the third wiring layer including the wiring WL3 is coupled to the fourth wiring layer including the wiring WL4 by plug.

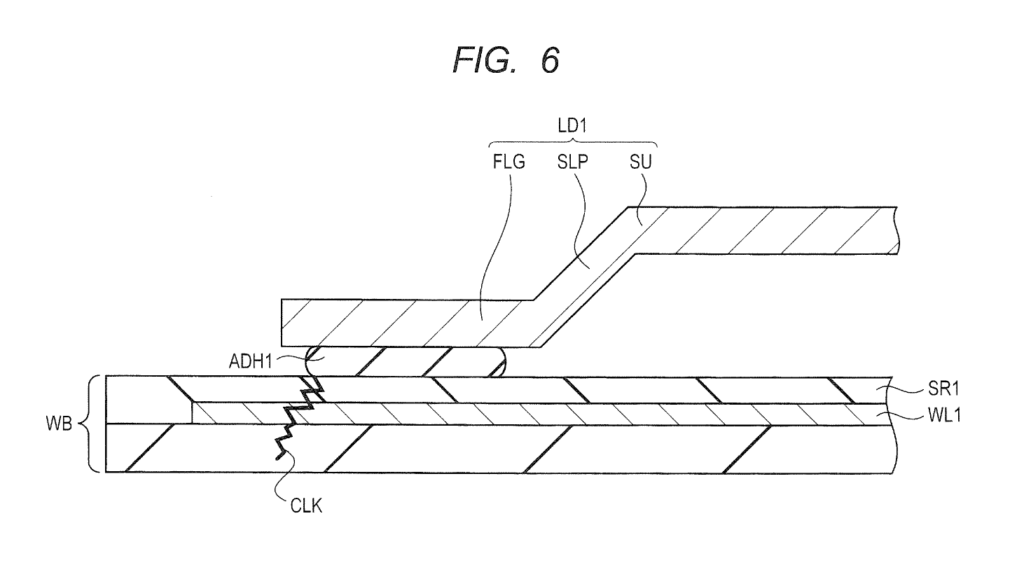

When the lid is adhered to the wiring substrate WB thus included through the adhesive, if the first wiring layer exists in the layer under the adhesive area where to apply the adhesive, the inventor et al. have found that a disconnection failure may occur in the wiring included in the first wiring layer. Specifically, FIG. 6 is a view schematically showing the state in which the wiring WL1 included in the first wiring layer of the wiring substrate WB is broken due to the adhesive ADH1 of adhering the lid LD1 to the wiring substrate WB. In FIG. 6, the wiring WL1 is formed in the first wiring layer positioned nearest to the surface of the wiring substrate WB and the solder resist film SR1 is formed to cover the wiring WL1. On the surface of the solder resist film SR1, the adhesive ADH1 is applied and through the adhesive ADH1, the flange portion FLG of the lid LD1 is adhered to the surface of the solder resist film SR1.

According to the investigation by the inventor et al., stress caused by the shrinkage of the adhesive ADH1 easily concentrates on the application area of the adhesive ADH1 and the stress concentration causes a crack CLK as shown in FIG. 6 starting from the solder resist film SR1. The inventor el al. have found that this crack CLK arrives in the wiring WL1 of the first wiring layer covered with the solder resist film SR1 and that a disconnection failure may occur in the wiring WL1. In short, when the wiring WL1 forming the first wiring layer exists at the position overlapping with the application area of the adhesive ADH1 in plan view, a disconnection failure easily occurs in the wiring WL1. In the embodiment, further improvement is performed in order to prevent the disconnection failure of the wiring WL1 in the first wiring layer due to the stress concentration of the adhesive ADH1. The further characteristic in the improved embodiment will be hereinafter described.

### Further Characteristic in the Embodiment

The basic spirit to prevent a disconnection failure of the wiring WL1 in the first wiring layer caused by the stress concentration of the adhesive ADH1 is to restrict the application area of the adhesive ADH1 for adhering the lid LD1 to the wiring substrate WB. In this basic spirit, the application area (adhesive area) of the adhesive ADH1 is not famed at the position overlapping with the wiring WL1 forming the first wiring layer in plan view. In other words, in the above mentioned basic spirit, the application area of the adhesive ADH1 is formed at the other position than the overlapping position with the wiring WL1 forming the first wiring layer in plan view. This basic spirit will be specifically described with reference to the drawings.

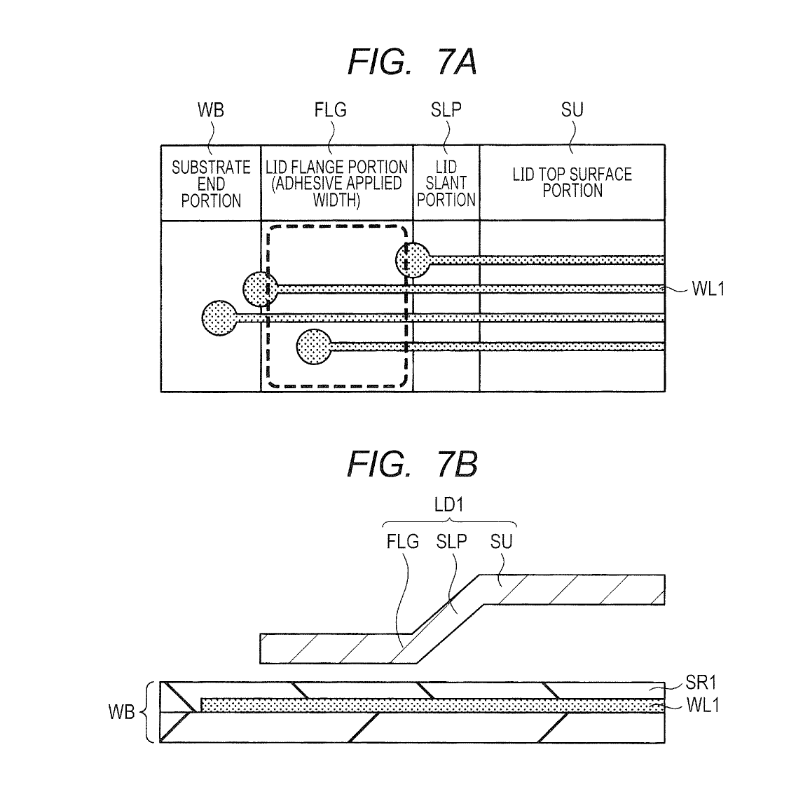

FIGS. 7A and 7B are views schematically showing the structure of not forming the application area (adhesive area) of the adhesive ADH1 at the overlapping position with the wiring WL1 forming the first wiring layer in plan view. Especially, FIG. 7A is a view schematically showing the positional relation among the wiring substrate WB, the lid LD1, and the wiring WL1 in plan view and FIG. 7B is a cross-sectional view schematically showing that the adhesive area of the adhesive ADH1 for adhering the lid LD1 is not formed above the wiring WL1.

At first, FIG. 7A shows a constitutional example in which the wiring WL1 forming the first wiring layer in the wiring substrate WB extends at the overlapping position with the flange portion FLG of the lid LD1 in plan view. In this case, as shown in FIG. 7B, the flange portion FLG of the lid LD1 and the wiring substrate WB (solder resist film SR1) are not adhered by the adhesive ADH1. This can prevent generation of a crack caused by the concentration of the stress of the adhesive ADH1 in the overlapping area with the wiring WL1 in plan view. As the result, the disconnection failure of the wiring WL1 caused by the crack can be prevented. In other words, in the embodiment, the flange portion FLG of the lid LD1 overlapping with the wiring WL1 included in the first wiring layer is a non-adhesive portion. Thus, in the embodiment, the adhesive ADH1 is not applied at the overlapping position with the wiring WL1 in plan view in the outermost surface covered with the solder resist film SR1, hence to suppress the generation of a crack itself caused by the stress concentration according to the shrinkage of the adhesive ADH1. As the result, according to the embodiment, it is possible to avoid the disconnection failure of the wiring WL1 due to the crack in advance.

The lid LD1, however, has to be fixed to the wiring substrate WB by the adhesive ADH1; therefore, all the area of the flange portion FLG of the lid LD1 cannot be a non-adhesive portion but some portion of the flange portion FLG has to be adhered to the wiring substrate WB by the adhesive ADH1. In the below, an example of a possible adhesive place to fix the flange portion FLG to the lid LD1 and the wiring substrate WB will be described.

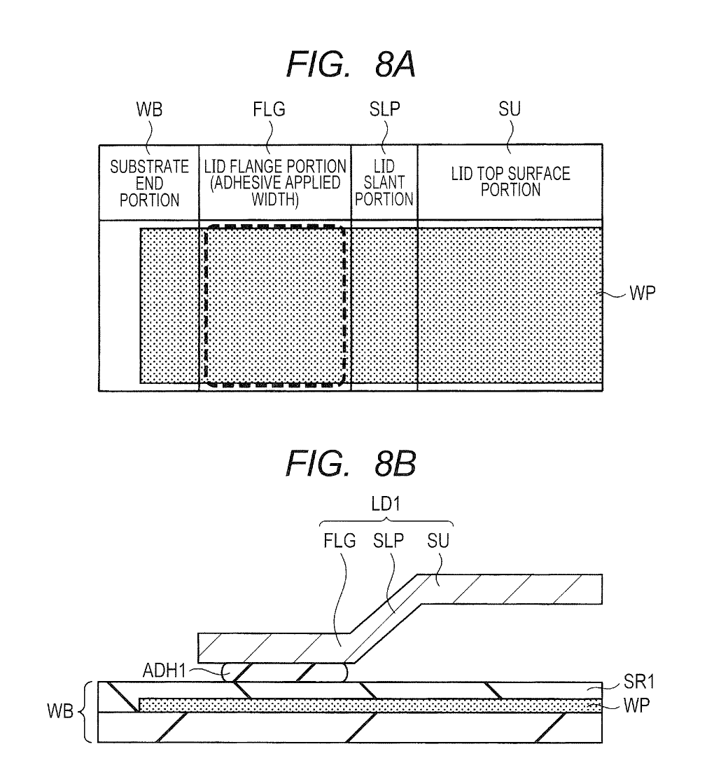

FIGS. 8A and B are views schematically showing that a wide pattern (solid pattern) WP of a large area is formed in the same layer as the first wiring layer and that the overlapping position with this wide pattern WP in plan view can be a possible application area (adhesive area) of the adhesive ADH1. Especially, FIG. 8A schematically shows the flat positional relation among the wiring substrate WB, the lid LD1, and the wide pattern WP and FIG. 8B is a cross-sectional view schematically showing that the adhesive area of the adhesive ADH1 for adhering the lid LD1 can be formed above the wide pattern WP.

Here, the “wide pattern WP” means a pattern having a larger width than the wiring width of the wiring WL1 forming the first wiring layer.

FIG. 8A shows a constitutional example in which the wide pattern WP expands in the same layer as the first wiring layer of the wiring substrate WB at the overlapping position with the flange portion FLG of the lid LD1 in plan view. In this case, as shown in FIG. 8B, the flange portion FLG of the lid LD1 and the wiring substrate WB (solder resist film SR1) can be adhered by the adhesive ADH1. The lid LD1 can be adhered to the wiring substrate WB by the adhesive ADH1. In other words, the flange portion FLG of the lid LD1 overlapping with the wide pattern WP in plan view is to contain the adhesive portion. The reason why the flange portion FLG of the lid LD1 overlapping with the wide pattern WP formed in the same layer as the first wiring layer in plan view can be adhered to the wiring substrate WB (solder resist SR1) by the adhesive ADH1 is as follows. Also in this case, a crack easily occurs in the solder resist film SR1 of the underlayer of the adhesive area, because of the stress concentration according to the shrinkage of the adhesive ADH1. Even when a crack occurs and the crack arrives at the wide pattern WP, the width of the wide pattern WP is much larger than the wiring width of the wiring WL1 shown in FIGS. 7A and 7B. Therefore, even when the crack arrives at the wide pattern WP, a possibility of generating the disconnection failure of the wide pattern WP is small. Further the wide pattern WP is seldom used as a signal wiring but often used for the purpose of stabilization of a reference potential (GND) and dummy pattern; therefore, even when a disconnection failure occurs in the wide pattern WP, it does not become a problem. Because of the above reasons, in the embodiment, the flange portion FLG of the lid LD1 overlapping with the wide pattern WP in plan view is the possible adhesive portion. According to this, in the embodiment, it is possible to adhere the lid LD1 to the wiring substrate WB by the adhesive ADH1 while avoiding the application of the adhesive ADH1 at the overlapping position with the wiring WL1 in the outermost surface covered with the solder resist film SR1 and while preventing the disconnection failure of the wiring WL1 due to the crack.

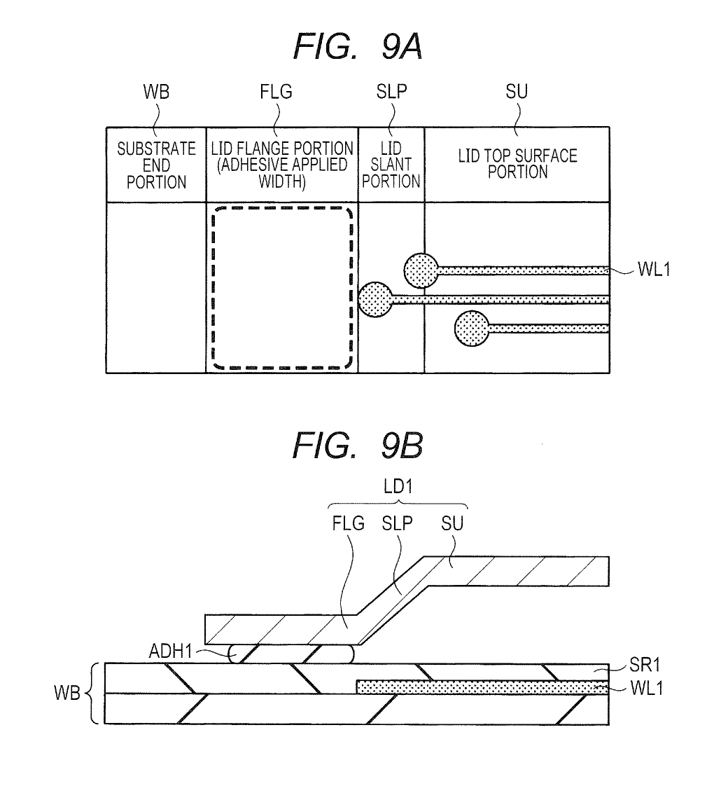

Next, FIGS. 9A and 9B are views schematically showing that with the wiring WL1 formed in the first wiring layer, the application area (adhesive area) of the adhesive ADH1 is formed at a position not overlapping with the wiring WL1 in plan view. Especially, FIG. 9A is a view schematically showing the flat positional relation among the wiring substrate WB, the lid LD1, and the wiring WL1 and FIG. 9B is a cross-sectional view schematically showing that adhesive area of the adhesive ADH1 to attach the lid LD1 can be provided in the area not overlapping with the wiring WL1 in plan view.

FIG. 9A shows a constitutional example in which the wiring WL1 formed in the first wiring layer of the wiring substrate WB expands at a position not overlapping with the flange portion FLG of the lid LD1 in plan view. In this case, as shown in FIG. 9B, the flange portion FLG of the lid LD1 can be adhered to the wiring substrate WB (solder resist film SR1) by the adhesive ADH1. According to this, the lid LD1 and the wiring substrate WB can be adhered to each other by the adhesive ADH1. Specifically, the flange portion FLG of the lid LD1 not overlapping with the wiring WL1 in plan view is to contain the adhesive portion. According to this, the reason why the flange portion FLG of the lid LD1 not overlapping with the wiring WL1 in plan view can be formed in an adhesive way to the wiring substrate WB (solder resist SR1) by the adhesive ADH1 formed in the first wiring layer is as follows. Also, in this case, because of the stress concentration according to the shrinkage of the adhesive ADH1, a crack easily occurs in the solder resist film SR1 in the underlayer of the adhesive area. Even when a crack occurs, since the wiring WL1 is not formed in the underlayer of the adhesive area, the crack hardly arrives at the area not overlapping with the adhesive area in plan view; therefore, even when a crack occurs, a possibility of generating a disconnection failure in the wiring WL1 not overlapping with the adhesive area in plan view is small. According to the above reason, in the embodiment, the flange portion FLG of the lid LD1 not overlapping with the wiring WL1 in plan view is defined as the adhesive portion. According to this, in the embodiment, the adhesive ADH1 is not applied at the position overlapping with the wiring WL1 in the outermost surface covered with the solder resist film SR1, to avoid the disconnection failure in the wiring WL1 caused by a crack, and the lid LD1 can be adhered to the wiring substrate WB by the adhesive ADH1.

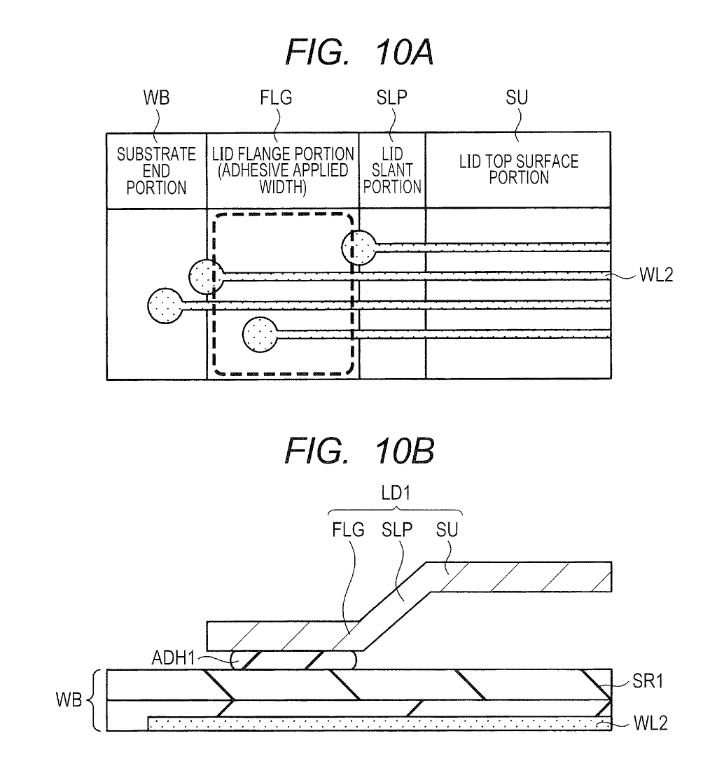

Continuously, FIGS. 10A and 10B are views schematically showing that the wiring WL2 is formed in the second wiring layer and that the application area (adhesive area) of the adhesive ADH1 is formed at the overlapping position with the wiring WL2 in plan view. Especially, FIG. 10A is a view schematically showing the flat positional relation among the wiring substrate WB, the lid LD1, and the wiring WL2 and FIG. 10B is a cross-sectional view schematically showing that the adhesive area of the adhesive ADH1 to adhere the lid LD1 can be provided in the overlapping area with the wiring WL2 in plan view.

FIG. 10A shows a constitutional example in which the wiring WL2 formed in the second wiring layer of the wiring substrate WB expands at a position overlapping with the flange portion FLG of the lid LD1 in plan view. In this case, as shown in FIG. 10B, the flange portion FLG of the lid LD1 can be adhered to the wiring substrate WB (solder resist film SR1) by the adhesive ADH1. According to this, the lid LD1 and the wiring substrate WB can be adhered to each other by the adhesive ADH1. The flange portion FLG of the lid LD1 overlapping with the wiring WL2 in plan view is to contain the adhesive portion. The reason why the flange portion FLG of the lid LD1 overlapping with the wiring WL2 formed in the second wiring layer in plan view can be formed to be adhered to the wiring substrate WB (solder resist SR1) by the adhesive ADH1 is as follows. Also in this case, because of the stress concentration according to the shrinkage of the adhesive ADH1, a crack easily occurs in the solder resist film SR1 in the underlayer of the adhesive area. Even when a crack occurs, since the wiring is not formed in the first wiring layer nearest to the adhesive area, of the underlayers of the adhesive area, even when the crack arrives at the first wiring layer, a disconnection failure does not occur. The wiring WL2 included in the second wiring layer is formed in the underlayer of the first wiring layer positioned further lower than the underlayer of the adhesive area; the second wiring layer is positioned at a further deeper position than the first wiring layer and therefore, a crack hardly arrives at this position and even if a crack occurs, a possibility of generating a disconnection failure in the wiring WL2 in the second wiring layer overlapping with the adhesive area in plan view is small. According to the above reason, in the embodiment, the flange portion FLG of the lid LD1 overlapping with the wiring WL2 of the second wiring layer in plan view is the possible adhesive area. In the embodiment, the adhesive ADH1 is not applied at the position overlapping with the wiring WL1 in the outermost surface covered with the solder resist film SR1 in plan view, to avoid the disconnection failure in the wiring WL1 caused by a crack, the lid LD1 can be adhered to the wiring substrate WB by the adhesive ADH1.

As mentioned above, thus realized is the basic spirit of forming the application area (adhesive area) of the adhesive ADH1 at the other position than the overlapping position with the wiring WL1 forming the first wiring layer in plan view. Hereinafter, the concrete constitutional example for realizing the basic spirit will be described.

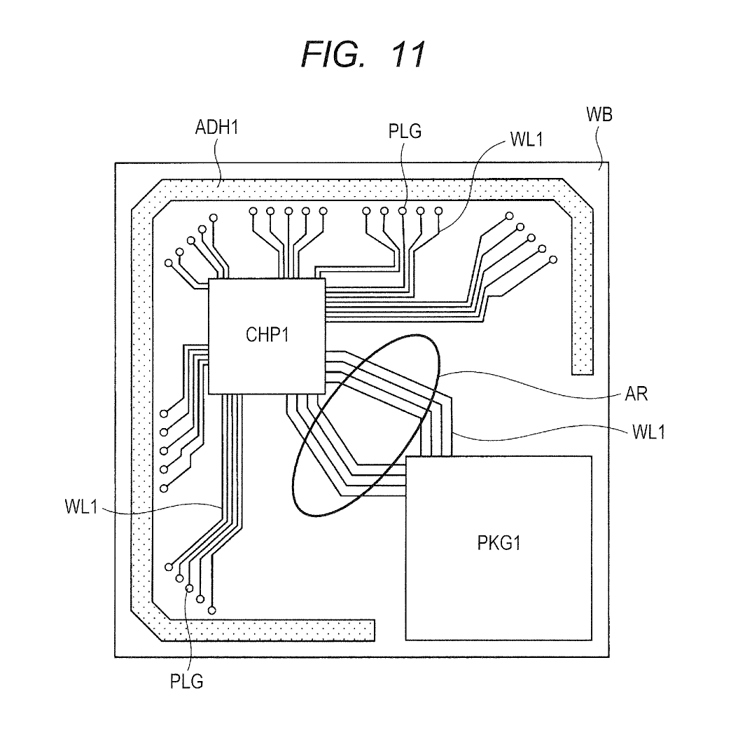

FIG. 11 is a schematic view showing the layout constitutional example of the wiring substrate WB in the embodiment. In FIG. 11, the semiconductor chip CHP1 with the central processing unit formed and the package structure PKG1 of sealing a semiconductor chip with a nonvolatile memory formed, are mounted in a rectangular wiring substrate WB. A plurality of wirings WL1 are formed in the wiring substrate WB. As shown in FIG. 5, multi-layer wiring is formed in the wiring substrate WB; in FIG. 11, a plurality of wirings WL1 are formed in the position nearest to the surface of the wiring substrate WB. As shown in FIG. 11, the semiconductor chip CHP1 and the package structure PKG1 mounted on the wiring substrate WB are electrically coupled by the plural wirings WL1. According to this, the central processing unit formed in the semiconductor chip CHP1 can control the nonvolatile memory formed in the semiconductor chip within the package structure PKG1. For example, other wirings WL1 extending in the fringe portion of the wiring substrate WB are also formed in the wiring substrate WB. Then, the adhesive ADH1 is applied to the fringe portion of the wiring substrate WB.

Here, in the embodiment, the lid made of a metal material is arranged to cover the semiconductor chip CHP1 and fixed to the surface of the wiring substrate WB without overlapping with the package structure PKG1 in plan view. As apparent from FIG. 11, the wiring WL1 formed in the area AR of FIG. 11 has a portion overlapping with the flange portion of the lid in plan view. In the embodiment, the basic spirit shown in FIG. 7 is applied to the wiring WL1 formed in the area AR of FIG. 11 so that the flange portion of the lid may not be adhered to the wiring substrate WB by the adhesive ADH1. According to this, it is possible to avoid a crack caused by the stress concentration of the adhesive ADH1 from occurring in the area AR overlapping with the wiring WL1 in plan view. As the result, a disconnection failure in the wirings WL1 caused by a crack can be avoided. In short, in the wiring substrate WB in the embodiment shown in FIG. 11, the flange portion of the lid overlapping with the wirings WL1 in the area AR included in the first wiring layer in plan view is a non-adhesive portion.

Further, in the embodiment, as shown in FIG. 11, the wirings WL1 included in the first wiring layer are not formed in the fringe portion of the wiring substrate WB but the adhesive ADH1 is applied to the fringe portion of the wiring substrate WB. In other words, in the wiring substrate WB shown in FIG. 11, the basic spirit shown in FIG. 9 is realized in the fringe portion. According to this, while avoiding the disconnection failure in the wirings WL, the wiring substrate WB can be adhered to the flange portion of the lid arranged in the fringe portion of the wiring substrate WB not overlapping with the wirings WL1 in plan view, by the adhesive ADH1.

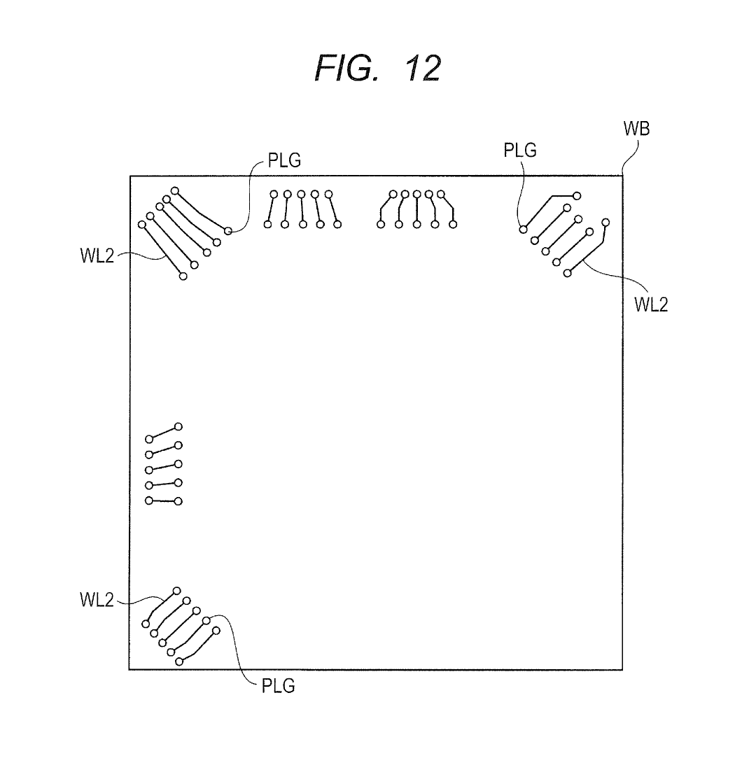

In the structure shown in FIG. 11, however, since the wirings WL1 do not extend to the fringe portion of the wiring substrate WB, some wiring has to be extended to the fringe portion of the wiring substrate WB, finally to be electrically coupled to the soldering balls formed in the fringe portion on the rear surface of the wiring substrate WB. In the embodiment, as shown in FIG. 11, the wirings WL1 included in the first wiring layer are coupled to plugs PLG without extending to the fringe portion of the wiring substrate WB. As shown in FIG. 12, the wirings WL2 included in the second wiring layer are extended to the fringe portion of the wiring substrate WB. Here, the wirings WL1 included in the first wiring layer shown in FIG. 11 are electrically coupled to the wirings WL2 included in the second wiring layer shown in FIG. 12 through the plugs PLG. Further, the wirings WL2 shown in FIG. 12 are electrically coupled to the wirings WL3 in the third wiring layer and the wirings WL4 in the fourth wiring layer shown in FIG. 5, through the through-holes formed in the core substrate, and finally electrically coupled to the soldering balls formed in the fringe portion on the rear surface of the wiring substrate WB. In this case, the wirings WL2 shown in FIG. 12 and the application area of the adhesive ADH1 shown in FIG. 11 overlap with each other in plan view; however, the second wiring layer where the wirings WL2 are formed is formed in the deeper position than the first wiring layer where the wirings WL1 are formed, and a crack hardly arrives at this position. Therefore, even when a crack occurs in the underlayer of the adhesive area, a possibility of generating a disconnection failure up to the wirings WL2 in the second wiring layer overlapping with the adhesive area in plan view is considered smaller. According to the above, in the embodiment, the adhesive area is formed in the area overlapping with the wiring WL2 in the second wiring layer in plan view. As mentioned above, the basis spirit shown in FIG. 7 is applied to the wirings WL1 formed in the area AR of FIG. 11 and the basic spirit shown in FIG. 10 is applied to the wirings WL2 formed in the fringe portion of FIG. 12, in the wiring substrate WB in the embodiment shown in FIGS. 11 and 12. In other words, according to the wiring substrate WB shown in FIGS. 11 and 12, the basic spirit that the application area (adhesive area) of the adhesive ADH1 is provided at any other position than the position overlapping with the wiring WL1 forming the first wiring layer in plan view is realized, which can avoid the disconnection failure of the wiring WL1 in the first wiring layer caused by the stress concentration of the adhesive ADH1.

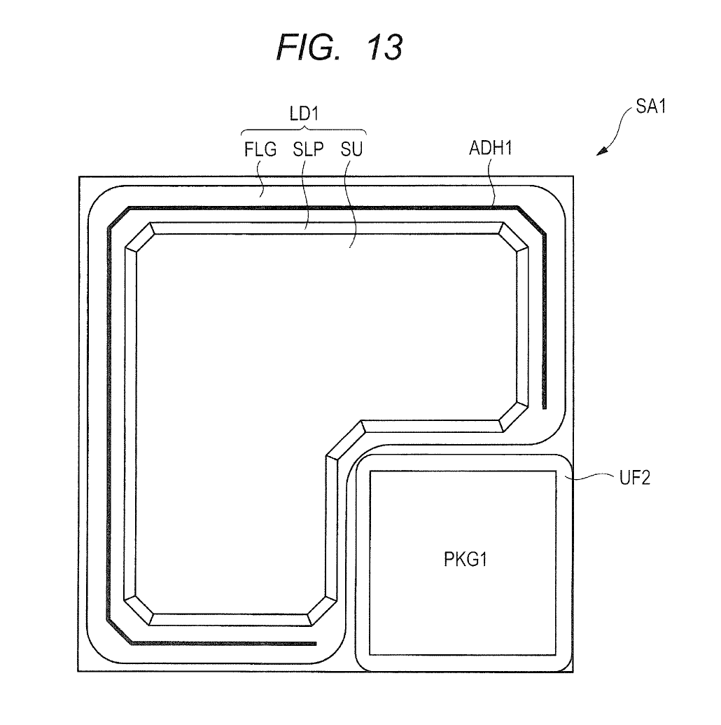

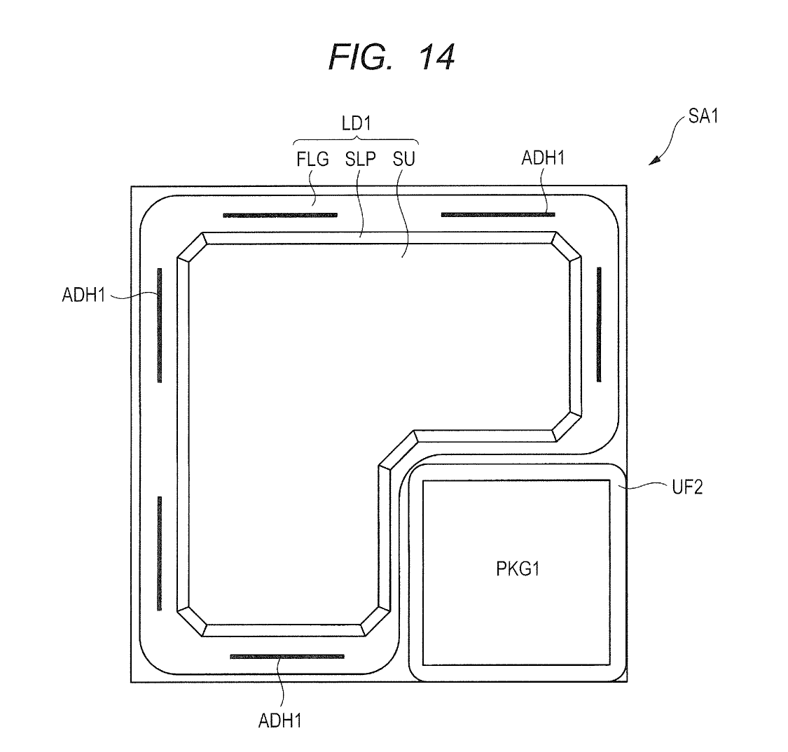

FIG. 13 is a top plan view showing the state with the lid LD1 mounted on the wiring substrate WB shown in FIG. 11. As shown in FIG. 13, the wiring substrate WB is adhered to the flange portion FLG of the lid LD1 by the adhesive ADH1 improved in the application area. However, as shown in FIG. 13, it is not restricted to the structure of continuously forming the application area of the adhesive ADH1 but, for example, the structure of discontinuously forming the application area of the adhesive ADH1 as shown in FIG. 14 may be adopted.

### <Manufacturing Method of Semiconductor Device>

The semiconductor device according to the embodiment is included as mentioned above, and its manufacturing method will be hereinafter described with reference to the drawings.

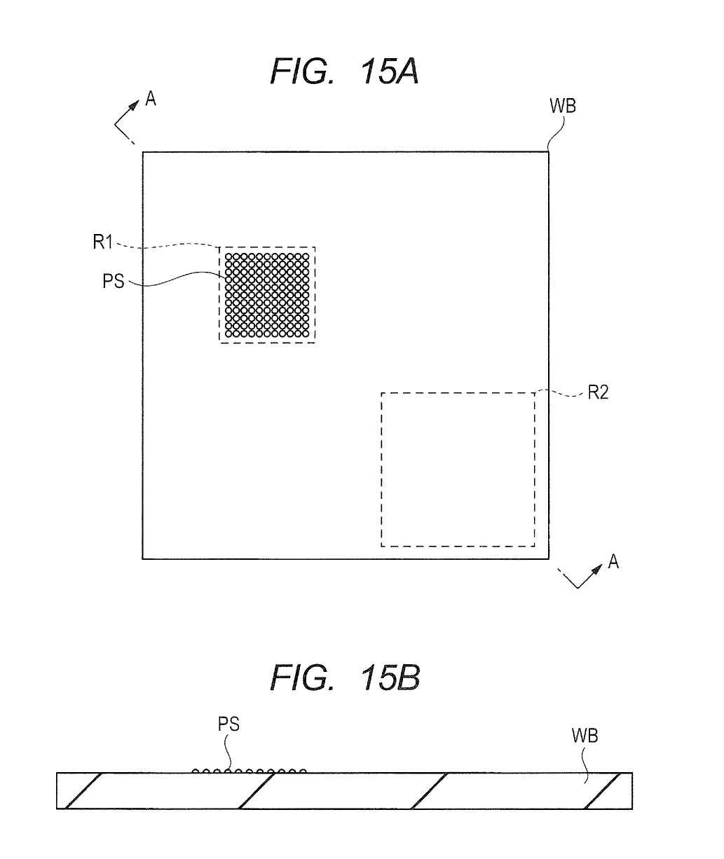

At first, as shown in FIGS. 15A and 15B, a wiring substrate WB is prepared. The surface of the wiring substrate WB includes a chip mounting area (first area) R1 where to mount a semiconductor chip and a package mounting area (second area) R2 where to mount a package structure, as shown in FIG. 15A. An opening portion (not illustrated) where to expose a terminal (electrode) is formed in the chip mounting area R1 and a preliminary solder PS is formed in the terminal exposed from the opening portion, for example, as shown in FIG. 15B. Further, an opening portion (not illustrated) where to expose a terminal (electrode) is also formed in the package mounting area R2 and the surface treatment is applied to the terminal exposed from the opening portion. As the surface treatment, for example, the electroless plating treatment with Ni/Pd/Au can be used.

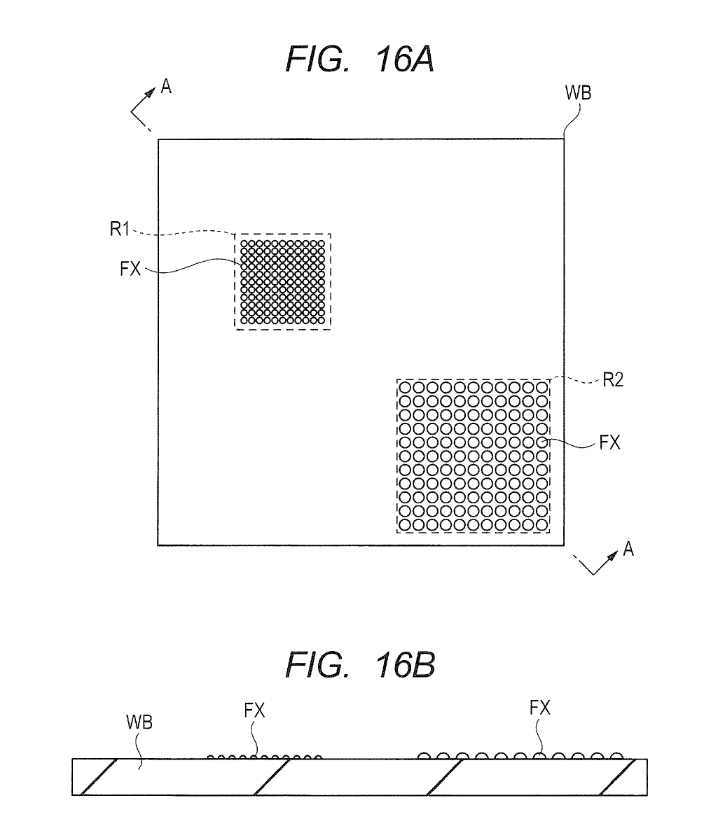

Then, as shown in FIGS. 16A and 16B, fluxes FX are formed in the terminals formed in the chip mounting area R1 and the package mounting area R2. For example, printing technique and pin transfer technique can be used for these fluxes FX. The fluxes FX can be formed in the chip mounting area R1 by using the printing technique and the pin transfer technique, while in the package mounting area R2, preliminary solder paste can be printed instead of the fluxes FX.

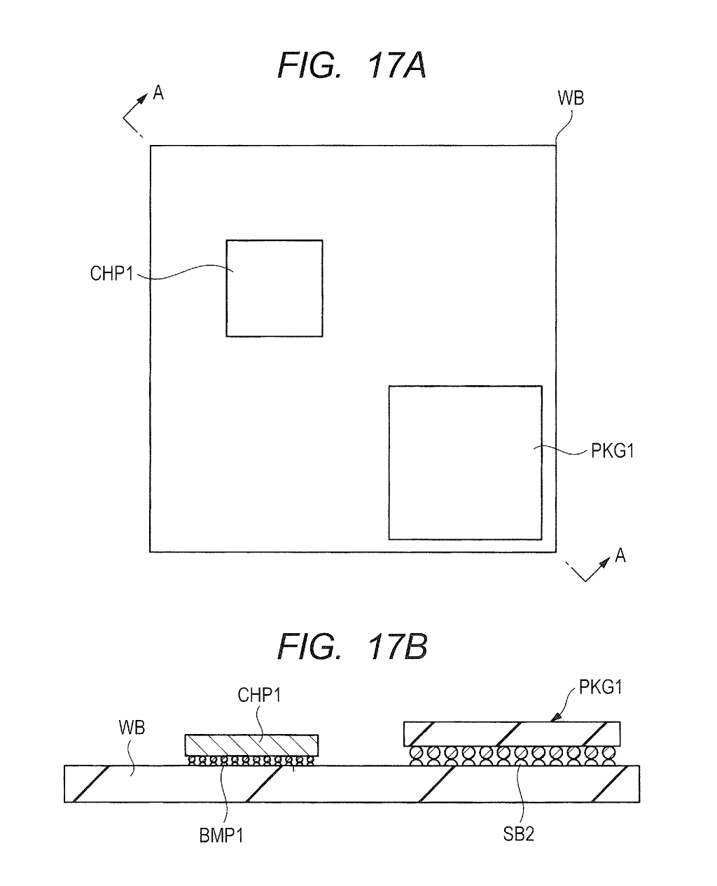

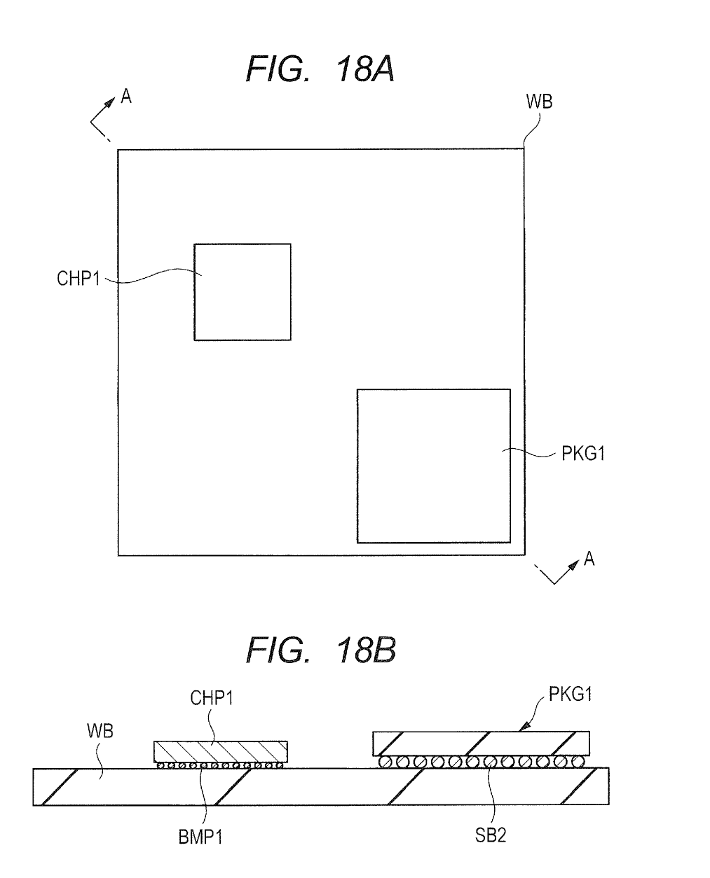

As shown in FIGS. 17A and 17B, at first, the package structure PKG1 is mounted on the package mounting area R2 in the wiring substrate WB, and then, the semiconductor chip CHP1 is mounted on the chip mounting area R1 in the wiring substrate WB. The mounting order of the package structure PKG1 and the semiconductor chip CHP1 is not restricted to the above but, for example, the semiconductor chip CHP1 is first mounted on the chip mounting area R1 in the wiring substrate WB, and then, the package structure PKG1 may be mounted on the package mounting area R2 in the wiring substrate WB. Here, the semiconductor chip CHP1 is mounted on the surface of the wiring substrate WB so that the bump electrodes BMP1 formed on the rear surface of the semiconductor chip CHP1 may be coupled to the terminals formed in the wiring substrate WB. Similarly, the package structure PKG1 is mounted on the surface of the wiring substrate WB so that the soldering balls SB2 formed on the rear surface of the package structure PKG1 may be coupled to the terminals formed in the wiring substrate WB. Then, as shown in FIGS. 18A and 18B, reflow treatment (thermal treatment) is performed on the wiring substrate WB where the semiconductor chip CHP1 and the package structure PKG1 are mounted. According to this, the bump electrodes BMP1 of the semiconductor chip CHP1 can be coupled to the terminals of the wiring substrate WB by solder and at the same time, the soldering balls SB2 of the package structure PKG1 can be coupled to the terminals of the wiring substrate WB by solder.

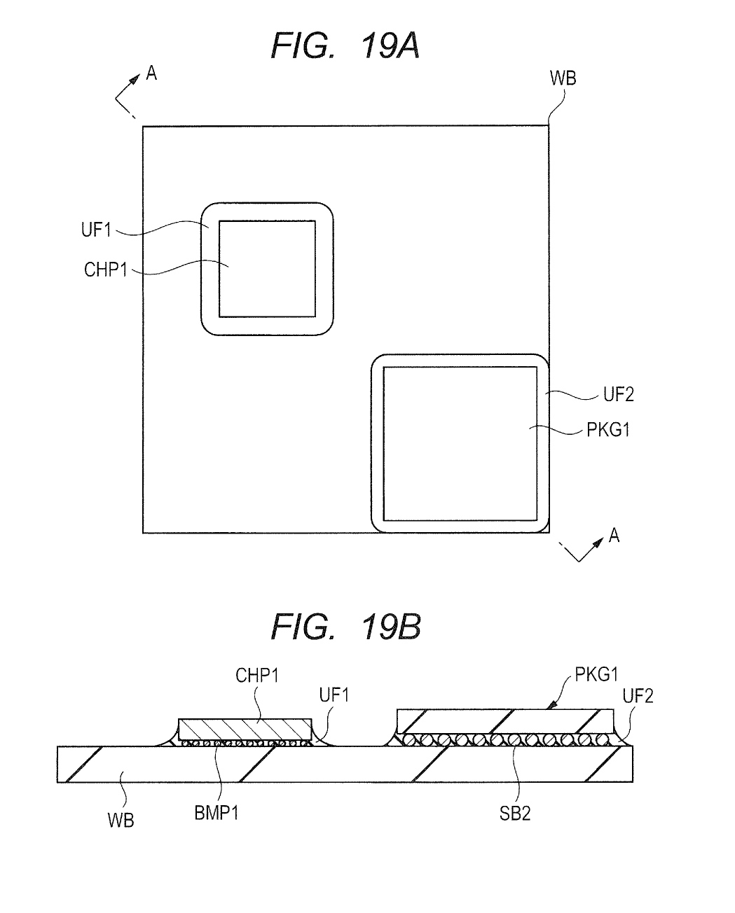

As shown in FIGS. 19A and 19B, after the flux cleaning as the preprocessing, baking treatment (heating treatment) is performed. For example, after filling the interstice between the semiconductor chip CHP1 and the wiring substrate WB with the underfill UF1, the interstice between the package structure PKG1 and the wiring substrate WB is filled with the underfill UF2. Here, for example, the underfill UF1 and the underfill UF2 may be formed of different materials. In this case, the underfill UF1 suitable for improvement of the joint reliability between the semiconductor chip CHP1 and the wiring substrate WB can be used and the underfill UF2 suitable for improvement of the joint reliability between the package structure PKG1 and the wiring substrate WB can be used. On the other hand, the underfill UF1 and the underfill UF2 may be formed of the same material. In this case, the manufacturing cost as well as the number of the processes can be reduced.

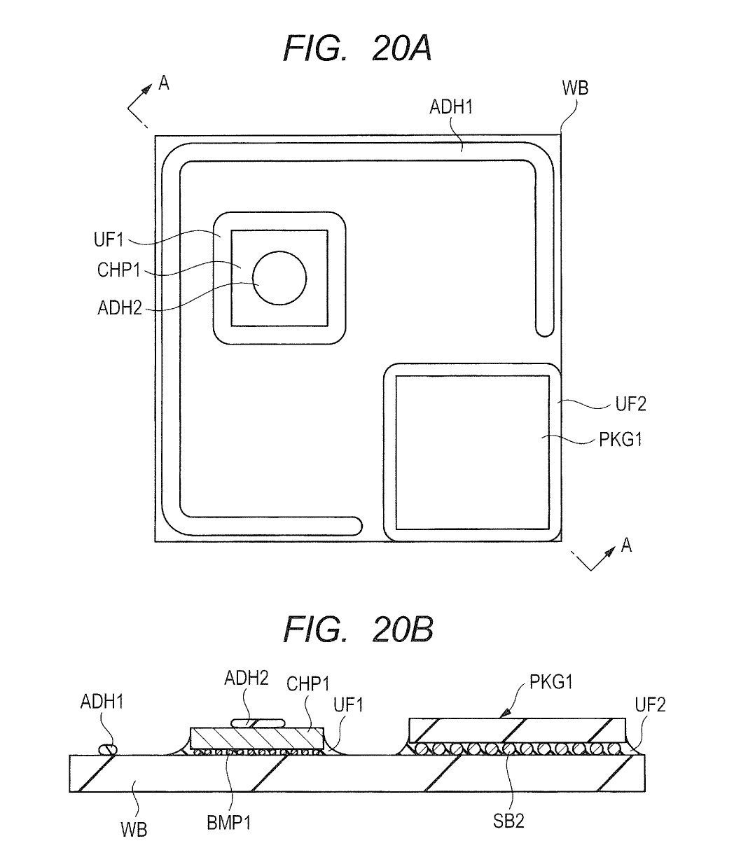

As shown in FIGS. 20A and 20B, the adhesive ADH1 is applied to a part of the fringe portion of the wiring substrate WB and further the adhesive ADH2 is applied to the semiconductor chip CHP1. Here, the application area of the adhesive ADH1 is formed without overlapping with the first wiring layer in plan view formed in the upmost layer nearest to the surface of the wiring substrate WB.

The adhesive ADH1 and the adhesive ADH2 are formed of different materials. For example, as the adhesive ADH1, a thermosetting resin mainly made of epoxy resin can be used and further in order to reinforce the material strength, a filler containing silicon oxide can be blended in the thermosetting resin. On the other hand, as the adhesive ADH2, a rubber resin mainly made of silicon resin can be used. Further, in order to enhance the thermal conductivity, a filler containing metal or metal oxide can be blended there.

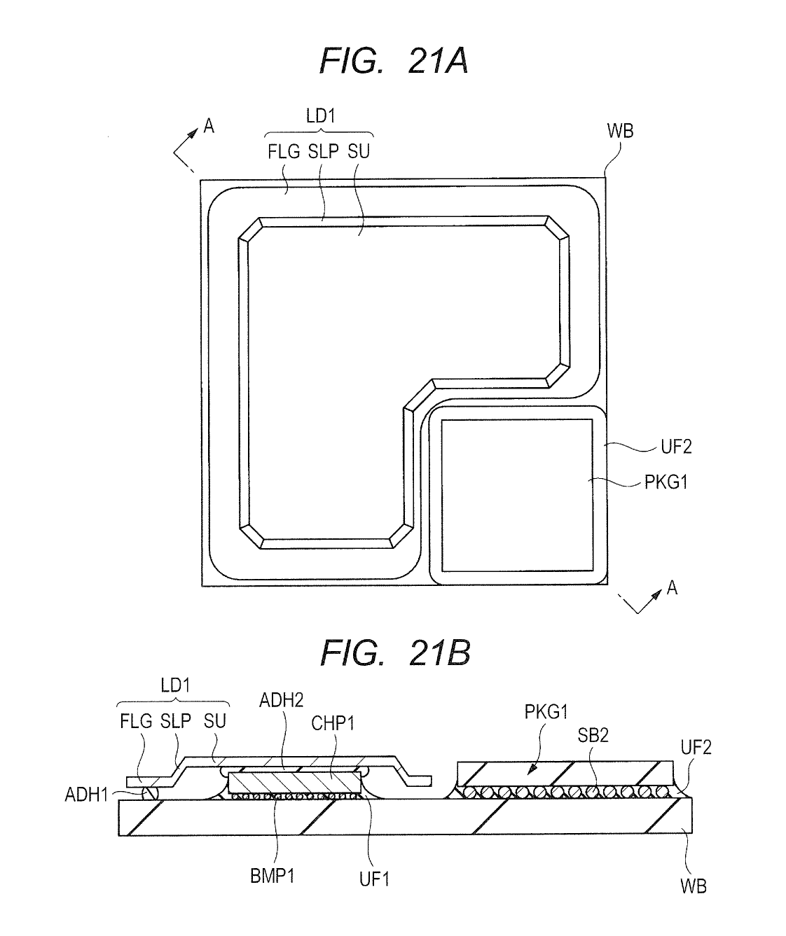

Then, as shown in FIGS. 21A and 21B, the lid LD1 made of a metal material is arranged on the wiring substrate WB to cover the semiconductor chip CHP1 without overlapping with the package structure PKG1 in plan view. Here, the lid LD1 has, in plan view, the upper surface portion SU overlapping the semiconductor chip CHP1, the flange portion FLG fixed to the surface of the wiring substrate WB, and the slant portion SLP for coupling the upper surface portion SU and the flange portion FLG. The applied adhesive ADH1 fixes the lid LD1 to the surface of the wiring substrate WB. Here, since the application area of the adhesive ADH1 is formed without overlapping with the first wiring layer, in plan view, formed in the upmost layer nearest to the surface of the wiring substrate WB, the flange portion FLG of the lid LD1 has an adhesive portion with the adhesive ADH1 attached there and a non-adhesive portion without the adhesive ADH1.

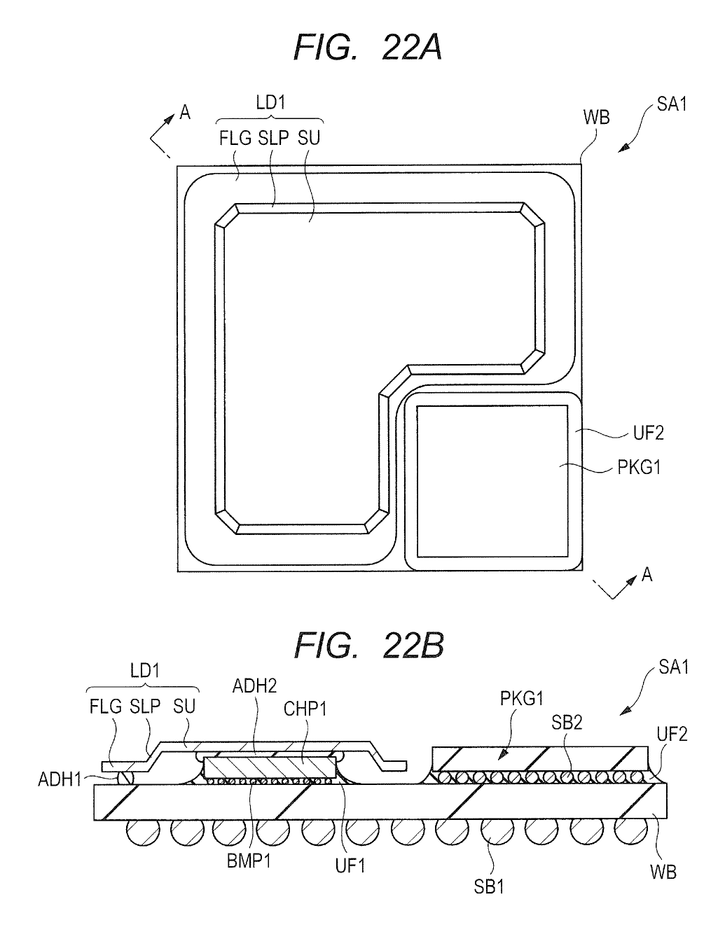

Then, as shown in FIGS. 22A and 22B, with a plurality of soldering balls SB1 mounted on the rear surface of the wiring substrate WB, the reflow treatment is performed. As mentioned above, the semiconductor device SA1 according to the embodiment can be manufactured.

### Modified Example 1

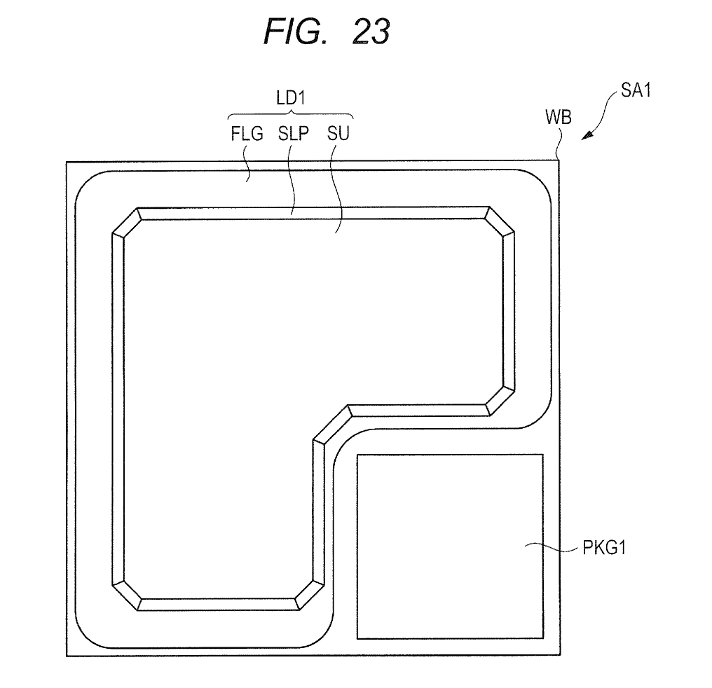

FIG. 23 is a top plan view showing the plane structure of a semiconductor device SA2 according to a modified example 1. In FIG. 23, the underfill is not formed in the interstice between the package structure PKG1 and the wiring substrate WB, in the semiconductor device SA2 according to the modified example 1. As mentioned above, the formation of the underfill can be saved and in this case, the manufacturing cost of the semiconductor device SA2 can be reduced.

### Modified Example 2

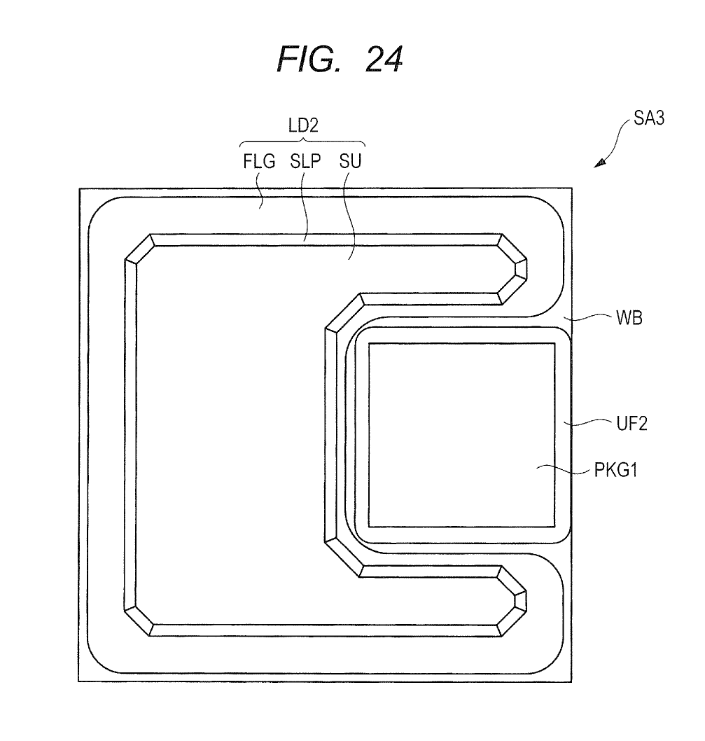

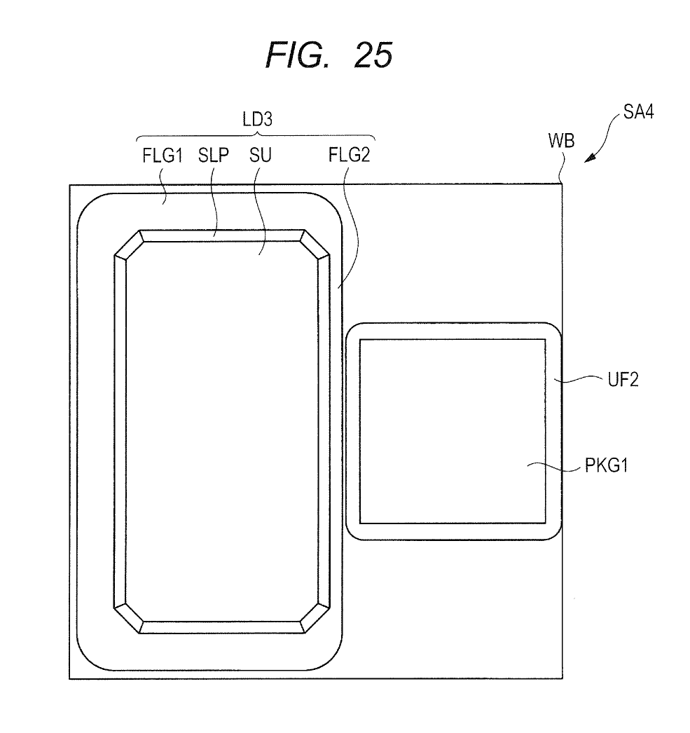

FIG. 24 is a top plan view showing the plane structure of a semiconductor device SA3 according to a modified example 2. In FIG. 24, a concave portion is formed in the lid LD2 and the package structure PKG1 can be arranged to be inserted in this concave portion, in the semiconductor device SA3 according to the modified example 2.

### Modified Example 3

FIG. 25 is a top plan view showing the plane structure of a semiconductor device SA4 according to a modified example 3. In FIG. 25, the plane shape of the lid LD3 is rectangular, including a flange portion FLG1 and a flange portion FLG2 having different widths, in the semiconductor device SA4 according to the modified example 3. Especially, the width of the flange portion FLG2 adjacent to the package structure PKG1 is smaller than the width of the flange portion FLG1. This is because a wiring for coupling the package structure PKG1 and the semiconductor chip covered with the lid LD3, included in the first wiring layer formed in the upmost layer nearest to the surface of the wiring substrate WB, is formed in the layer under the flange portion FLG2 and the adhesive is not formed in the area overlapping with the flange portion FLG2 in plan view. The flange portion FLG2 of the lid LD3 is a non-adhesive portion without the adhesive or a portion which does not contribute to the improvement of the adhesive strength of the lid LD3; therefore, in the modified example 3, the width of the flange portion FLG2 is formed smaller than the width of the other adhesive portion, that is, the flange portion FLG1. According to this, the semiconductor device SA4 according to the modified example 3 can be downsized.

### Modified Example 4

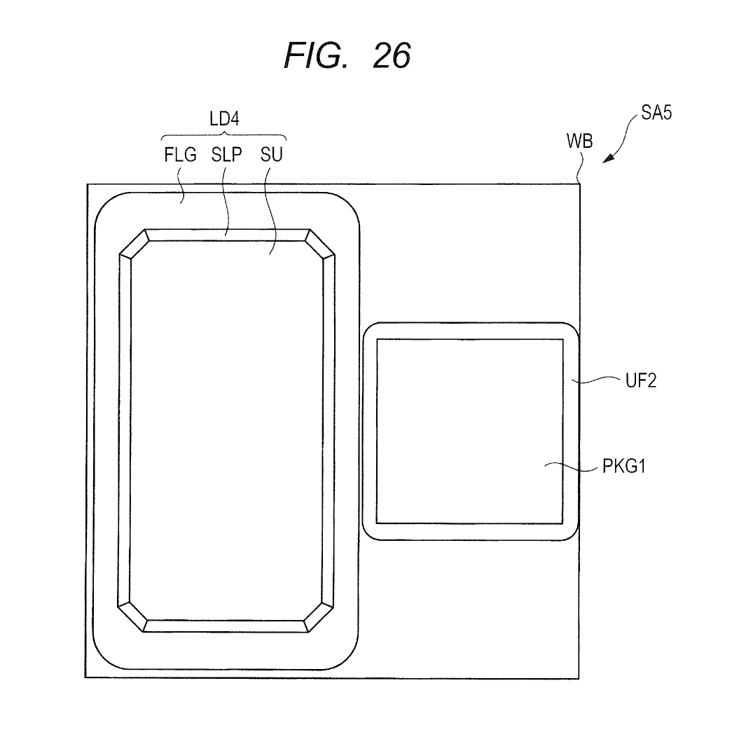

FIG. 26 is a top plan view showing the plane structure of a semiconductor device SA5 according to a modified example 4. In FIG. 26, the plane shape of the lid LD4 is rectangular in the semiconductor device SA5 according to the modified example 4. Here, for example, the wiring for coupling the package structure PKG1 to the semiconductor chip covered with the lid LD3 can be formed by a wiring in the wiring layer deeper than the first wiring layer famed in the upmost layer nearest to the surface of the wiring substrate WB. In this case, according to the modified example 4, the whole flange portion FLG of the lid LD4 can be an adhesive portion. Therefore, according to the modified example 4, by making the width of a part of the flange portion FLG adjacent to the package structure PKG identical to the width of the other part thereof, the joint strength of the lid LD4 can be improved.

As set forth hereinabove, the invention made by the inventor et al. has been specifically described according to the embodiments; however, it is needless to say that the invention is not restricted to the above embodiments but that various modifications are possible without departing from the spirit.

What is claimed is:

1. A semiconductor device comprising:
a substrate including a surface;
a first semiconductor chip mounted over a first area of the surface of the substrate;
a package structure mounted over a second area of the surface of the substrate;
a metal material for covering the first semiconductor chip, which is fixed to the surface of the substrate without overlapping with the package structure on plan view;
wherein the metal material includes
a first portion overlapping with the first semiconductor chip in plan view,
a second portion fixed to the surface of the substrate, and
a joint portion for jointing the first portion and the second portion, and
wherein a distance from the surface of the substrate to a top surface of the first portion is larger than a distance from the surface of the substrate to a top surface of the second portion.

2. The device according to claim 1,
wherein the second portion includes an adhesive portion with a first adhesive interposed between the same portion and the surface of the substrate and a non-adhesive portion without the first adhesive therebetween.

3. The device according to claim 2,
wherein in the substrate,
a first wiring is formed in a depth nearest to the surface, and
a second wiring is formed in a layer under the first wiring.

4. The device according to claim 3,
wherein a portion of the second portion overlapping with the first wiring in a plane is the non-adhesive portion.

5. The device according to claim 3,
wherein a portion of the second portion not overlapping with the first wiring in a plane includes the adhesive portion.

6. The device according to claim 5,
wherein a portion of the second portion overlapping with the second wiring in a plane includes the adhesive portion.

7. The device according to claim 5,
wherein in the substrate, a wide pattern with a larger width than a wiring width of the first wiring is formed in the same layer as the first wiring, and
wherein a portion of the second portion overlapping with the wide pattern in a plane includes the adhesive portion.

8. The device according to claim 2,
wherein a second adhesive intervenes between the first semiconductor chip and the metal material.

9. The device according to claim 8,
wherein the first adhesive and the second adhesive are formed of different materials.

10. The device according to claim 9,
wherein the first adhesive is famed of a resin including a filler containing silicon oxide, and
wherein the second adhesive is formed of a resin including a filler containing metal.

11. The device according to claim 1,
wherein a top surface of the metal material is higher than a top surface of the package structure.

12. The device according to claim 1,
wherein the package structure is thicker than the first semiconductor chip.

13. The device according to claim 1,
wherein a plane area of the metal material is larger than a plane area of the package structure.

14. The device according to claim 1,
wherein the first semiconductor chip is mounted over the first area of the surface of the substrate through a plurality of bump electrodes, and
wherein the package structure is mounted over the second area of the surface of the substrate through a plurality of ball terminals.

15. The device according to claim 14,
wherein a first underfill intervenes between the first semiconductor chip and the surface of the substrate,
wherein a second underfill intervenes between the package structure and the surface of the substrate, and
wherein the first underfill and the second underfill are formed of same material.

16. The device according to claim 14,
wherein a first underfill intervenes between the first semiconductor chip and the surface of the substrate,
wherein a second underfill intervenes between the package structure and the surface of the substrate, and
wherein the first underfill and the second underfill are formed of different materials.

17. The device according to claim 1,
wherein a second semiconductor chip exists within the package structure,
wherein a central processing circuit is famed in the first semiconductor chip, and
wherein a nonvolatile memory circuit is famed in the second semiconductor chip.

18. The device according to claim 1,
wherein a second semiconductor chip exists within the package structure,
wherein a first oscillator is formed within the first semiconductor chip,
wherein a second oscillator is formed within the second semiconductor chip, and
wherein an oscillation accuracy of the second oscillator is higher than the oscillation accuracy of the first oscillator.

19. The device according to claim 2,
wherein in the substrate,
a first wiring is formed in a depth nearest to the surface, and
a second wiring is formed in a layer under the first wiring,
wherein the first semiconductor chip and the package structure are electrically coupled together through the first wiring, and
wherein the non-adhesive portion is a portion overlapping with the first wiring in a plane.

20. A semiconductor device comprising:
a substrate including a surface;
a first semiconductor part mounted over a first area of the surface of the substrate;
a second semiconductor part mounted over a second area of the surface of the substrate; and
a heat radiating material for covering the first semiconductor part, which is fixed to the surface of the substrate, without overlapping with the second semiconductor part in plan view,
wherein the heat radiating material includes
a first portion overlapping with the first semiconductor part in plan view,
a second portion fixed to the surface of the substrate, and
a joint portion for jointing the first portion and the second portion,
wherein a distance from the surface of the substrate to a top surface of the first portion is larger than a distance from the surface of the substrate to a top surface of the second portion.
